(19) United States
(12) Patent Application Publication
(10) Pub. No.: US 2026/0081419 A1
(43) Pub. Date: Mar. 19, 2026

(54) THRESHOLD VOLTAGE ADJUSTMENT CIRCUIT AND SEMICONDUCTOR INTEGRATED CIRCUIT

(71) Applicants: Kabushiki Kaisha Toshiba, Tokyo (JP); Toshiba Electronic Devices & Storage Corporation, Tokyo (JP)

(72) Inventor: Toyoaki UO, Yokohama Kanagawa (JP)

(21) Appl. No.: 19/067,185

(22) Filed: Feb. 28, 2025

(30) Foreign Application Priority Data
Sep. 18, 2024 (JP) 2024-160793

(51) Int. Cl. H02H 9/04; H02H 1/00; H02H 7/00; H02H 9/02; H10D 89/60

(52) U.S. Cl. CPC H02H 9/045; H02H 1/0007; H02H 7/008; H02H 9/02; H10D 89/60

(57) ABSTRACT

A threshold voltage adjustment circuit of an embodiment includes a reference current circuit and a trans-impedance circuit. The reference current circuit is formed on a substrate and outputs a reference current. The trans-impedance circuit has a plurality of resistors on the substrate, and outputs a threshold voltage that is expressed as a function of a reference current and a combined resistance of the plurality of resistors and an external resistor.

### CROSS-REFERENCE TO RELATED APPLICATION

This application is based upon and claims the benefit of priority from Japanese Patent Application No. 2024-160793, filed Sep. 18, 2024; the entire contents of which are incorporated herein by reference.

### FIELD

Embodiments described herein relate generally to a threshold voltage adjustment circuit and a semiconductor integrated circuit.

### BACKGROUND

As a method for detecting an overcurrent in a power element, a non-saturated voltage detection method for detecting a non-saturated voltage of the power element is generally known. In the non-saturated voltage detection method, when the non-saturated voltage of a power element exceeds a predetermined threshold voltage, it is determined that an overcurrent has flowed through the power element. In the non-saturated voltage detection method, it is necessary to adjust the threshold voltage to various values in order to accommodate various types of power elements and to resolve a trade-off between a speeding-up of an overcurrent detection operation and improving noise resistance.

### BRIEF DESCRIPTION OF THE DRAWINGS

FIG. 1 is a circuit diagram showing a configuration of a semiconductor integrated circuit according to a first embodiment.

FIG. 2 is a timing chart showing a voltage waveform at each of terminals of the semiconductor integrated circuit according to the first embodiment.

FIG. 3 is a circuit diagram showing a configuration of a threshold voltage adjustment circuit according to the first embodiment.

FIG. 4 is a graph showing results of calculating a threshold voltage for a resistance value of an external resistor.

FIG. 5 is a circuit diagram showing a first modified example of the threshold voltage adjustment circuit.

FIG. 6 is a circuit diagram showing an example of a configuration of a PTAT current source.

FIG. 7 is a circuit diagram showing a second modified example of the threshold voltage adjustment circuit.

FIG. 8 is a circuit diagram showing a third modified example of the threshold voltage adjustment circuit.

FIG. 9 is a circuit diagram showing a configuration of a semiconductor integrated circuit according to a second embodiment.

FIG. 10 is a timing chart showing a voltage waveform at each of terminals of the semiconductor integrated circuit according to the second embodiment.

FIG. 11 is a circuit diagram showing an example of a configuration of a threshold voltage detection circuit.

FIG. 12 is a circuit diagram showing an example of a configuration of a constant current source included in an overcurrent detection circuit.

FIG. 13 is a circuit diagram showing an example of a semiconductor integrated circuit 1A including an insulation element.

FIG. 14 is a circuit diagram showing an example in which a primary-side chip includes an insulation element.

FIG. 15 is a circuit diagram showing an example in which an insulation chip including an insulation element is disposed between a primary chip and a secondary chip.

FIG. 16 is a circuit diagram showing an example in which both the primary chip and the secondary chip include an insulation element.

FIG. 17 is a circuit diagram showing a first example of the semiconductor integrated circuit including an optical device as the insulation element.

FIG. 18 is a circuit diagram showing a second example of the semiconductor integrated circuit including an optical device as the insulation element.

### DETAILED DESCRIPTION

A threshold voltage adjustment circuit of an embodiment includes a reference current circuit and a trans-impedance circuit. The reference current circuit is formed on a substrate and outputs a reference current. The trans-impedance circuit has a plurality of resistors on the substrate, and outputs a threshold voltage that is expressed as a function of a reference current and a combined resistance of the plurality of resistors and an external resistor.

Hereinafter, a threshold voltage adjustment circuit and a semiconductor integrated circuit according to embodiments will be described with reference to the drawings.

### First Embodiment

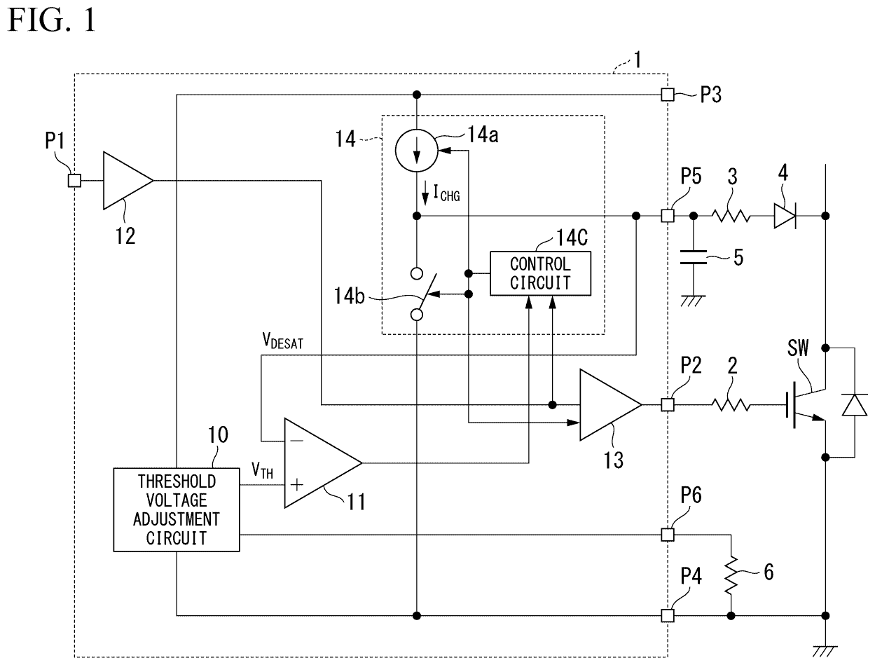

FIG. 1 is a circuit diagram showing a configuration of a semiconductor integrated circuit 1 according to a first embodiment. The semiconductor integrated circuit 1 is a gate drive circuit that drives a gate of a power element SW. In this embodiment, an IGBT is exemplified as the power element SW, but the power element SW to be driven by the semiconductor integrated circuit 1 may be other power elements such as a Si-MOSFET and a SIC-MOSFET.

As shown in FIG. 1, the semiconductor integrated circuit 1 includes an input terminal P1, an output terminal P2, a power supply terminal P3, a ground terminal P4, an overcurrent detection terminal P5, a resistor connection terminal P6, a threshold voltage adjustment circuit 10, a comparator 11, an input buffer 12, a first output buffer 13, and an overcurrent detection circuit 14.

The input terminal P1 is a terminal to which a timing signal for controlling a turn-on timing and a turn-off timing of the power element SW is input. For example, the timing signal is a PWM signal. The output terminal P2 is a terminal which outputs a gate drive signal that drives the gate of the power element SW. The gate drive signal has approximately the same pulse width as the timing signal and has an amplitude larger than that of the timing signal. The output terminal P2 is electrically connected to the gate of the power element SW via a gate resistor 2.

The power supply terminal P3 is a terminal to which a power supply potential V_{CC2}, which is a positive potential with respect to a ground potential V_{GND}, is applied. The ground terminal P4 is a terminal to which the ground potential V_{GND} is applied. The ground terminal P4 is electrically connected to both the ground and an emitter of the power element SW.

The overcurrent detection terminal P5 is a terminal that outputs a detection current I_{CHG} for detecting an overcurrent in the power element SW. The overcurrent detection terminal P5 is electrically connected to a collector of the power element SW via a resistor 3 and a diode 4. Moreover, the overcurrent detection terminal P5 is electrically connected to the ground via a capacitor 5. One end of the resistor 3 is electrically connected to both the overcurrent detection terminal P5 and one end of the capacitor 5. The other end of the resistor 3 is electrically connected to an anode of the diode 4. A cathode of the diode 4 is electrically connected to the collector of the power element SW.

The resistor connection terminal P6 is a terminal for connecting an external resistor 6 to the semiconductor integrated circuit 1. One end of the external resistor 6 is electrically connected to the resistor connection terminal P6. The other end of the external resistor 6 is electrically connected to the ground terminal P4. FIG. 1 shows a case in which the external resistor 6 is connected between the resistor connection terminal P6 and the ground terminal P4, but the external resistor 6 may also be connected between the resistor connection terminal P6 and the power supply terminal P3. The case in which the external resistor 6 is connected between the resistor connection terminal P6 and the power supply terminal P3 will be described below.

The threshold voltage adjustment circuit 10 is electrically connected to the power supply terminal P3, the ground terminal P4, the resistor connection terminal P6, and a non-inverting input terminal of the comparator 11. The threshold voltage adjustment circuit 10 outputs a threshold voltage V_{TH} to the non-inverting input terminal of the comparator 11. Although details will be described below, the threshold voltage V_{TH} output from the threshold voltage adjustment circuit 10 varies according to a resistance value of the external resistor 6 connected to the resistor connection terminal P6.

An inverting input terminal of the comparator 11 is electrically connected to the overcurrent detection terminal P5. The comparator 11 compares the threshold voltage V_{TH} output from the threshold voltage adjustment circuit 10 with a voltage at the overcurrent detection terminal P5 and outputs a signal indicating a comparison result to the overcurrent detection circuit 14. In the following description, the voltage at the overcurrent detection terminal P5 may be referred to as a detection terminal voltage V_{DESAT}. For example, when the detection terminal voltage V_{DESAT} is equal to or lower than the threshold voltage V_{TH}, the comparator 11 outputs a first level signal to the overcurrent detection circuit 14. Furthermore, the comparator 11 outputs a second level signal to the overcurrent detection circuit 14 when the detection terminal voltage V_{DESAT} exceeds the threshold voltage V_{TH}. For example, the first level signal is a low level signal, and the second level signal is a high level signal.

For example, the comparator 11 is preferably a hysteresis comparator. Although not shown in FIG. 1, preferably, a low-pass filter, a voltage buffer, and the like are disposed between the inverting input terminal of the comparator 11 and the overcurrent detection terminal P5.

An input terminal of the input buffer 12 is electrically connected to the input terminal P1. An output terminal of the input buffer 12 is electrically connected to an input terminal of the first output buffer 13. The input buffer 12 is an example of an input circuit to which a timing signal is input via the input terminal P1. The input buffer 12 shapes a waveform of the timing signal input via the input terminal P1 and outputs the shaped timing signal to the first output buffer 13. Preferably, a filter for removing a glitch when a glitch occurs at the input terminal P1 is mounted in the input buffer 12. The input buffer 12 also outputs the shaped timing signal to the overcurrent detection circuit 14.

An output terminal of the first output buffer 13 is electrically connected to the output terminal P2. The first output buffer 13 receives a first control signal output as an input from the overcurrent detection circuit 14 in addition to the timing signal output from the input buffer 12. When the level of the first control signal is low, the first output buffer 13 generates a gate drive signal in synchronization with the timing signal input via the input buffer 12, and outputs the gate drive signal via the output terminal P2.

The first output buffer 13 outputs a gate drive signal that changes between the ground potential V_{GND} and the power supply potential V_{CC2} in synchronization with the timing signal. When the level of the first control signal is high, the first output buffer 13 outputs a gate drive signal having the ground potential V_{GND}, regardless of the timing signal. The first output buffer 13 is an example of a first output circuit. The potential of the ground terminal P4 may be lower than the emitter potential of the power element SW. In this case, the first output buffer 13 outputs a gate drive signal that changes between the power supply potential V_{CC2} and a minus potential with respect to the emitter potential of the power element SW.

The overcurrent detection circuit 14 is electrically connected to the power supply terminal P3, the ground terminal P4, and the overcurrent detection terminal P5. The overcurrent detection circuit 14 receives the output signal of the comparator 11 and the timing signal output from the input buffer circuit 12 as an input. The overcurrent detection circuit 14 detects a rise of the timing signal input via the input circuit 12 and then outputs a detection current I_{CHG} via the overcurrent detection terminal P5 after a certain time has elapsed.

After the output signal of the comparator 11 changes from a low level to a high level, the overcurrent detection circuit 14 controls the first output buffer 13 so that a gate drive signal having a potential that sets the power element SW to an OFF state is output. Specifically, after the output signal of the comparator 11 changes from a low level to a high level, the overcurrent detection circuit 14 controls the first output buffer 13 so that a gate drive signal having the ground potential V_{GND} is output.

The overcurrent detection circuit 14 controls the first output buffer 13 by outputting a first control signal to the first output buffer 13. After the output signal of the comparator 11 changes from a low level to a high level, the overcurrent detection circuit 14 changes the first control signal from a low level to a high level. As described above, when the level of the first control signal is high, the first output buffer 13 outputs a gate drive signal having the ground potential V_{GND}, regardless of the timing signal.

The overcurrent detection circuit 14 includes a constant current source 14a, a switch 14b, and a control circuit 14c. The constant current source 14a is electrically connected between the power supply terminal P3 and the switch 14b. The switch 14b is electrically connected between the constant current source 14a and the ground terminal P4. A connection point between the constant current source 14a and the switch 14b is electrically connected to the overcurrent detection terminal P5. The constant current source 14a outputs the detection current I_{CHG}. A timing at which the detection current I_{CHG} is output from the constant current source 14a to the overcurrent detection terminal P5 is controlled by the control circuit 14c. The switch 14b is switched to an ON or OFF state by the control circuit 14c.

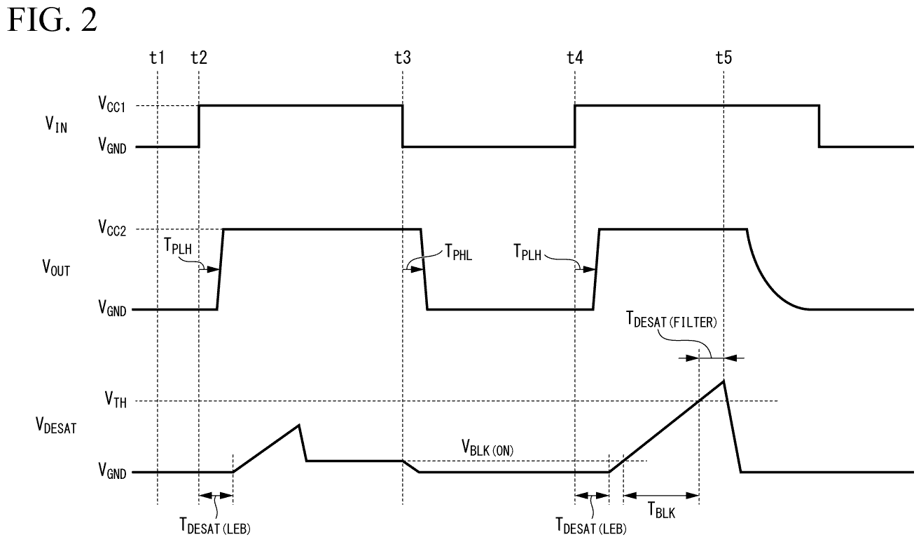

The control circuit 14c controls the timing at which the detection current I_{CHG} is output from the constant current source 14a on the basis of the timing signal. The control circuit 14c switches the switch 14b between the ON state and the OFF state on the basis of the timing signal. The control circuit 14c outputs the first control signal to the first output buffer 13. The control circuit 14c sets the level of the first control signal to a high level or a low level on the basis of the output signal of the comparator 11. Hereinafter, an operation of the control circuit 14c will be described in detail with reference to FIG. 2.

FIG. 2 is a timing chart showing a voltage waveform at each of terminals of the semiconductor integrated circuit 1. Specifically, the timing chart in FIG. 2 shows waveforms of an input terminal voltage V_{IN}, an output terminal voltage V_{OUT}, and a detection terminal voltage V_{DESAT}.

The input terminal voltage V_{IN} is a voltage of the input terminal P1 with respect to the ground potential V_{GND}. The input terminal voltage V_{IN} corresponds to the timing signal input to the input terminal P1. The output terminal voltage V_{OUT} is a voltage of the output terminal P2 with respect to the ground potential V_{GND}. The output terminal voltage V_{OUT} corresponds to the gate drive signal output from the output terminal P2. The detection terminal voltage V_{DESAT} is a voltage of the overcurrent detection terminal P5 with respect to the ground potential V_{GND}. In FIG. 2, V_{CC1} is a high-level potential of a digital signal such as a timing signal, or the like. V_{CC1} is lower than a power supply potential V_{CC2} applied to the power supply terminal P3.

As shown in FIG. 2, it is assumed that at a time t1, the input terminal voltage V_{IN} corresponding to the timing signal, and the detection terminal voltage V_{DESAT} are both at a low level (V_{GND}). Since the detection terminal voltage V_{DESAT} is equal to or lower than the threshold voltage V_{TH}, the output signal of the comparator 11 is at a low level. At such time t1, since the output signal of the comparator 11 is at a low level, the control circuit 14c outputs a first control signal at a low level to the first output buffer 13. When the level of the first control signal is low, the first output buffer 13 generates a gate drive signal in synchronization with the timing signal. As a result, at the time t1, the output terminal voltage V_{OUT} corresponding to the gate drive signal also becomes a low level (V_{GND}), and the power element SW is in the OFF state.

When the power element SW is in the OFF state, there is no need to detect an overcurrent in the power element SW. Therefore, in this case, the control circuit 14c may set the constant current source 14a to a disabled state and may set the switch 14b to the ON state or may set the switch 14b to the ON state while the constant current source 14a is in operation. The disabled state is a state in which the detection current I_{CHG} is not output from the constant current source 14a. As a result, since the detection terminal voltage V_{DESAT} becomes substantially equal to the ground potential V_{GND}, a charge is completely discharged from the capacitor 5.

At a time t2 after the time t1, when the input terminal voltage V_{IN} changes from a low level (V_{GND}) to a high level (V_{CC1}), after a predetermined propagation delay time T_{PLH} has elapsed, the output terminal voltage V_{OUT} also changes from a low level (V_{GND}) to a high level (V_{CC2}). As a result, the power element SW is switched from the OFF state to the ON state.

When the power element SW is in the ON state, it is necessary to detect an overcurrent in the power element SW. Therefore, when the input terminal voltage V_{IN} changes to a high level at the time t2, after a first standby time T_{DESAT(LEB)} has elapsed from the time t2, the control circuit 14c sets the constant current source 14a to an enabled state and sets the switch 14b to the OFF state or sets the switch 14b to the OFF state while the constant current source 14a is in operation. The enabled state is a state in which the detection current I_{CHG} is output from the constant current source 14a. As a result, the detection current I_{CHG} is output from the overcurrent detection terminal P5.

However, even when the output terminal voltage V_{OUT} changes from a low level to a high level, the power element SW is not immediately set to the ON state. In other words, for a certain period of time after the output terminal voltage V_{OUT} changes to a high level, since a collector terminal voltage of the power element SW is maintained in a high state, the diode 4 is biased in a reverse direction. As a result, the detection current I_{CHG} flows to the capacitor 5, and thus the detection terminal voltage V_{DESAT} rises from the ground potential V_{GND}.

When the power element SW is completely in the ON state before the detection terminal voltage V_{DESAT} reaches the threshold voltage V_{TH}, the diode 4 is biased in a forward direction. As a result, the detection current I_{CHG} flows to the collector of the power element SW via the resistor 3 and the diode 4, and thus the detection terminal voltage V_{DESAT} falls. When a value of the detection terminal voltage V_{DESAT} reaches a steady-state voltage value V_{BLK(ON)}, the value of the detection terminal voltage V_{DESAT} is maintained at the steady-state voltage value V_{BLK(ON)} while the power element SW is in the ON state. The steady-state voltage value V_{BLK(ON)} is expressed by the following Equation (1). In the following Equation (1), V_{CE(ON)} is a collector-emitter voltage of the power element SW in the ON state (a saturated state), V_{F} is a forward drop voltage of the diode 4, and R_{DESAT} is a resistance value of the resistor 3.

$$\begin{matrix}[ Equation 1 ] & \\ {V}_{BLK ( ON )} = {V}_{CE ( ON )} + {V}_{F} + {R}_{DESAT} \times {I}_{CHG} & ( 1 )\end{matrix}$$

At a time t3 after the time t2, when the input terminal voltage V_{IN} changes from a high level to a low level, the output terminal voltage V_{OUT} also changes from a high level to a low level after the predetermined propagation delay time T_{PHL} has elapsed. As a result, the power element SW switches from the ON state to the OFF state.

As described above, when the power element SW is in the OFF state, there is no need to detect an overcurrent in the power element SW. Therefore, when the input terminal voltage V_{IN} changes to a low level at the time t3, the control circuit 14c may set the constant current source 14a to the disabled state and may set the switch 14b to the ON state or may set the switch 14b to the ON state while the constant current source 14a is in operation. As a result, the charge is completely discharged from the capacitor 5, and thus the value of the detection terminal voltage V_{DESAT} falls from the steady-state voltage value V_{BLK(ON)} to the ground potential V_{GND}.

At a time t4 after the time t3, when the input terminal voltage V_{IN} changes from a low level to a high level, the output terminal voltage V_{OUT} also changes from a low level to a high level after the predetermined propagation delay time T_{PLH} has elapsed. As a result, the power element SW switches from the OFF state to the ON state.

Similar to the time t2, when the input terminal voltage V_{IN} changes to a high level at the time t4, after the first standby time T_{DESAT(LEB)} has elapsed from the time t4, the control circuit 14c sets the constant current source 14a to the enabled state and sets the switch 14b to the OFF state, or sets the switch 14b to the OFF state while the constant current source 14a is in operation. Here, when it is assumed that an overcurrent flows through the power element SW, the power element SW operates in a non-saturated state, and thus the collector-emitter voltage of the power element SW rises. As a result, due to the diode 4 being biased in the reverse direction, the detection current I_{CHG} flows through the capacitor 5, and thus the detection terminal voltage V_{DESAT} rises from the ground potential V_{GND}.

When an overcurrent continues to flow through the power element SW, the detection terminal voltage V_{DESAT} continues to rise with the passage of time. Then, when the detection terminal voltage V_{DESAT} exceeds the threshold voltage V_{TH}, the output signal of the comparator 11 changes from a low level to a high level.

At a time t5 when the detection terminal voltage V_{DESAT} exceeds the threshold voltage V_{TH}, that is, when a second standby time T_{DESAT(FILTER)} has elapsed from a point in time when the output signal of the comparator 11 changes to a high level, the control circuit 14c determines that an overcurrent has flowed through the power element SW, and changes the first control signal to be output to the first output buffer 13 from a low level to a high level. When the level of the first control signal is high, the first output buffer 13 outputs a gate drive signal having the ground potential V_{GND}, regardless of the timing signal. Therefore, after the second standby time T_{DESAT(FILTER)} has elapsed from a point in time when the detection terminal voltage V_{DESAT} exceeds the threshold voltage V_{TH}, the output terminal voltage V_{OUT} changes from a high level to a low level. As a result, when an overcurrent flows through the power element SW, the power element SW is forcibly switched to the OFF state.

When the power element SW is forcibly switched to the OFF state, it is desirable to implement in the first output buffer 13 a soft turn-off function that slowly changes the output terminal voltage V_{OUT} to a low level so that the power element SW is slowly switched to the OFF state.

In addition, after the second standby time T_{DESAT(FILTER)} has elapsed from a point in time when the detection terminal voltage V_{DESAT} exceeds the threshold voltage V_{TH}, the control circuit 14c sets the constant current source 14a to the disabled state and sets the switch 14b to the ON state or sets the switch 14b to the ON state while the constant current source 14a is in operation. As a result, the charge is completely discharged from the capacitor 5, and thus the value of the detection terminal voltage V_{DESAT} quickly falls to the ground potential V_{GND}.

As described above, even when no overcurrent flows through the power element SW, for a certain period of time after the output terminal voltage V_{OUT} changes from a low level to a high level, the collector terminal voltage of the power element SW is maintained in a high state, and thus, the diode 4 is biased in the reverse direction. As a result, since the detection current I_{CHG} flows to the capacitor 5, the detection terminal voltage V_{DESAT} rises from the ground potential V_{GND}. Therefore, it is necessary to set a capacitance C_{BLK} of the capacitor 5 so that the detection terminal voltage V_{DESAT} does not exceed the threshold voltage V_{TH} within a period in which the power element SW that is operating normally switches from the OFF state to the ON state.

For example, the capacitance C_{BLK} of the capacitor 5 is set so that the following Equation (2) is satisfied. In the following Equation (2), T_{BLK} is called a blanking time. This blanking time T_{BLK} needs to be set to a time shorter than a short circuit tolerance of the power element SW and longer than an ON time of the power element SW. Here, the ON time of the power element SW is a time it takes for the power element SW to switch from the OFF state to the ON state.

$$\begin{matrix}[ Equation 2 ] & \\ {T}_{BLK} = \frac{{C}_{BLK} \times ( {V}_{CE ( ON )} - {V}_{F} - {R}_{DESAT} \times {I}_{CHG} )}{{I}_{CHG}} & ( 2 )\end{matrix}$$

When noise generated from the power element SW is applied to the overcurrent detection terminal P5, the detection terminal voltage V_{DESAT} may exceed the threshold voltage V_{TH} even though no overcurrent is occurring. That is, the noise generated from the power element SW may cause the overcurrent detection circuit 14 to erroneously detect the occurrence of an overcurrent. In this case, even though the power element SW is normal, the power element SW is forcibly switched to the OFF state. In order to avoid erroneous detection of the overcurrent caused by such noise, the above-described first standby time T_{DESAT(LEB)} and second standby time T_{DESAT(FILTER)} are set.

There is a low-pass filter configured of the resistor 3, the diode 4, and the capacitor 5 between the overcurrent detection terminal P5 and the collector of the power element SW, but for high frequency noise, a divided voltage of a junction capacitance (CJ) of the diode 4 and the capacitance C_{BLK} of the capacitor 5 is applied to the overcurrent detection terminal P5. Therefore, increasing the capacitance C_{BLK} of the capacitor 5 is also an effective means for improving noise resistance. However, since the blanking time T_{BLK} needs to be shorter than the short-circuit tolerance of the power element SW, there is a limit to increase the capacitance C_{BLK} of the capacitor 5. Moreover, increasing the capacitance C_{BLK} of the capacitor 5 hinders speeding-up of an overcurrent detection operation. Also, reducing the junction capacitance by connecting the diode 4 in series is an effective means for improving noise resistance, but there are concerns about a rise in V_{BLK(ON)} and the number of components.

As described above, since there is a trade-off between the speeding-up of the overcurrent detection operation and the improvement of the noise resistance, it is necessary to set the capacitance C_{BLK} of the capacitor 5 so that the detection terminal voltage V_{DESAT} does not exceed the threshold voltage V_{TH} within the period in which the power element SW that is operating normally switches from the OFF state to the ON state, while taking this trade-off into consideration. In addition, since the necessary threshold voltage V_{TH} differs according to the type of the power element SW, it is necessary to take the type of the power element SW into consideration when the threshold voltage V_{TH} is set.

As described above, in order to accommodate various types of power elements SW and to resolve the trade-off between the speeding-up of the overcurrent detection operation and the improvement of the noise resistance, it is necessary to adjust the value of the threshold voltage V_{TH} to various values.

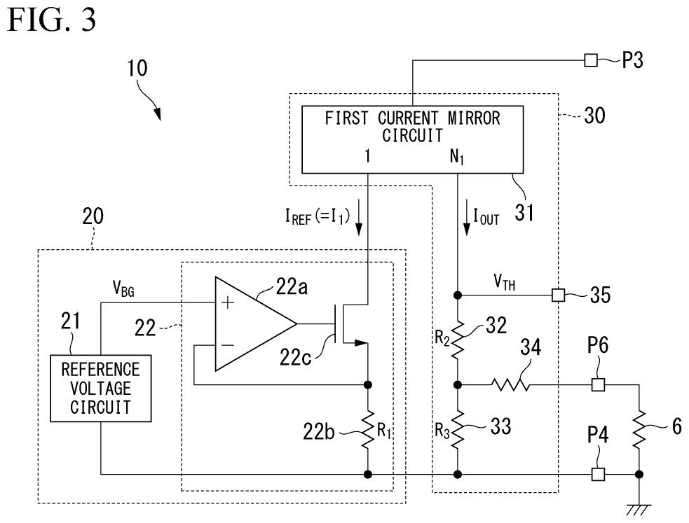

The threshold voltage V_{TH} output from the threshold voltage adjustment circuit 10 of this embodiment varies according to the resistance value of the external resistor 6 connected to the resistor connection terminal P6. That is, according to the threshold voltage adjustment circuit 10 of this embodiment, the threshold voltage V_{TH} can be easily adjusted by a simple method of simply changing the resistance value of the external resistor 6. Hereinafter, with reference to FIG. 3, a detailed description will be given of a configuration of the threshold voltage adjustment circuit 10 that can easily adjust the threshold voltage V_{TH} by such a simple method.

FIG. 3 is a circuit diagram showing a configuration of the threshold voltage adjustment circuit 10. As shown in FIG. 3, the threshold voltage adjustment circuit 10 includes a reference current circuit 20 and a trans-impedance circuit 30. The reference current circuit 20 is formed on the substrate and outputs a reference current I_{REF}. The trans-impedance circuit 30 has a first current mirror circuit and a plurality of resistors on the above-described substrate, and outputs the threshold voltage V_{TH} expressed as a function of the reference current I_{REF} and the combined resistance of the plurality of resistors and the external resistor 6. For example, the substrate in this embodiment is a silicon substrate.

The reference current circuit 20 includes a reference voltage circuit 21 and a first voltage controlled current source 22. The reference voltage circuit 21 outputs a reference voltage V_{BG} to the first voltage controlled current source 22. For example, the reference voltage circuit 21 is a bandgap reference (BGR) circuit. The first voltage controlled current source 22 outputs a first current I₁ proportional to the reference voltage V_{BG} as a reference current I_{REF}. In other words, the reference current I_{REF} output from the reference current circuit 20 is equal to the first current I₁ output from the first voltage controlled current source 22.

The first voltage controlled current source 22 includes an operational amplifier 22a, a resistor 22b, and a MOSFET element 22c. For example, the MOSFET element 22c is an N-channel MOSFET. A non-inverting input terminal of the operational amplifier 22a is electrically connected to an output terminal of the reference voltage circuit 21. The reference voltage V_{BG} output from the reference voltage circuit 21 is input to the non-inverting input terminal of the operational amplifier 22a. An inverting input terminal of the operational amplifier 22a is electrically connected to a source of the MOSFET element 22c. An output terminal of the operational amplifier 22a is electrically connected to a gate of the MOSFET element 22c.

One end of the resistor 22b is electrically connected to the source of the MOSFET element 22c. The other end of the resistor 22b is electrically connected to the ground terminal P4. A drain of the MOSFET element 22c is electrically connected to the trans-impedance circuit 30. A current flowing from the drain of the MOSFET element 22c toward the resistor 22b is the first current I₁, that is, the reference current I_{REF}.

The trans-impedance circuit 30 includes a first current mirror circuit 31, a resistor 32, a resistor 33, a resistor 34, and a threshold voltage output terminal 35. That is, the trans-impedance circuit 30 of this embodiment has three resistors 32, 33, and 34 as a plurality of resistors.

The first current mirror circuit 31 is electrically connected to the power supply terminal P3. An input terminal of the first current mirror circuit 31 is electrically connected to the drain of the MOSFET element 22c of the first voltage controlled current source 22. The first current mirror circuit 31 receives the reference current I_{REF} as an input and outputs a current Jour that is a multiple of the reference current I_{REF}. For example, the first current mirror circuit 31 outputs a current Jour that is N₁ times the reference current I_{REF}, where N₁ is a current mirror ratio.

One end of the resistor 32 is electrically connected to the output terminal of the first current mirror circuit 31. The other end of the resistor 32 is electrically connected to one end of the external resistor 6 via the resistor 34 and the resistor connection terminal P6. The resistor 32 is an example of a first resistor. One end of the resistor 33 is electrically connected to the other end of the resistor 32. The other end of the resistor 33 is electrically connected to the other end of the external resistor 6 via the ground terminal P4. The resistor 33 is an example of a second resistor.

One end of the resistor 34 is electrically connected to a connection point between the resistors 32 and 33. The other end of the resistor 34 is electrically connected to one end of the external resistor 6 via the resistor connection terminal P6. The resistor 34 is not essential, and the trans-impedance circuit 30 may include only the resistors 32 and 33 as the plurality of resistors. The threshold voltage output terminal 35 is a terminal that outputs the threshold voltage V_{TH} and is electrically connected to one end of the resistor 32. The threshold voltage output terminal 35 is electrically connected to the non-inverting input terminal of the comparator 11 shown in FIG. 1.

In the threshold voltage adjustment circuit 10 configured as above, the reference current I_{REF} output from the reference current circuit 20 is expressed by the following Equation (3). In the following Equation (3), ΔV_{BG} is a variation ratio of the reference voltage V_{BG}, R₁ is a resistance value of the resistor 22b, and ΔR is a variation ratio of the resistance value of each of the resistors formed inside the semiconductor integrated circuit 1. However, in order to achieve sufficient mismatch performance within the same semiconductor integrated circuit 1, the variation ratio of the resistance value of each of the resistors is set to the same in consideration of determination of a layout and size of each of the resistors.

$$\begin{matrix}[ Equation 3 ] & \\ {I}_{REF} = \frac{{V}_{BG}}{{R}_{1}} \cdot \frac{1 + Δ {V}_{BG}}{1 + Δ R} & ( 3 )\end{matrix}$$

The threshold voltage V_{TH} output from the trans-impedance circuit 30 is expressed by the following Equation (4). In the following Equation (4), ΔN₁ is a variation ratio of the current mirror ratio N₁ of the first current mirror circuit 31, and RT is a combined resistance of the resistors 32, 33, and 34 and the external resistor 6. As can be understood from the following Equation (4), the threshold voltage V_{TH} is expressed as a function of the reference current I_{REF} and the combined resistance RT of the resistors 32, 33, and 34, and the external resistor 6.

$$\begin{matrix}[ Equation 4 ] & \\ {V}_{TH} = {I}_{REF} \cdot {N}_{1} ( 1 + Δ {N}_{1} ) \cdot {R}_{T} & ( 4 )\end{matrix}$$

In the above Equation (4), when it is assumed that ΔR<<1, ΔN₁<<1, and ΔV_{BG}<<1, the above Equation (4) can be transformed into the following Equation (5). In the following Equation (5), R₂ is a resistance value of the resistor 32, R₃ is a resistance value of the resistor 33, R₄ is a resistance value of the resistor 34, and R_{EXT} is a resistance value of the external resistor 6.

$$\begin{matrix}[ Equation 5 ] & \\ {V}_{T H} \approx \frac{{N}_{1} {V}_{BG} {R}_{2}}{{R}_{1}} \cdot [ 1 + \frac{\frac{{R}_{4}}{{R}_{2}} + \frac{{R}_{EXT}}{{R}_{2}}}{1 + \frac{{R}_{2}}{{R}_{3}} \cdot ( \frac{{R}_{4}}{{R}_{2}} + \frac{{R}_{EXT}}{{R}_{2}} )} ] \cdot ( 1 + ε ) & ( 5 )\end{matrix}$$

In the above Equation (5), ε is a variation ratio of the threshold voltage V_{TH} and is expressed by the following Equation (6).

$$\begin{matrix}[ Equation 6 ] & \\ ε \approx - \frac{\frac{{R}_{EXT}}{{R}_{2}} ( 1 + \frac{{R}_{4}}{{R}_{2}} \cdot \frac{{R}_{2}}{{R}_{3}} )}{[ ( 1 + \frac{{R}_{2}}{{R}_{3}} ) ( \frac{{R}_{4}}{{R}_{2}} + \frac{{R}_{EXT}}{{R}_{2}} ) + 1 ] [ \frac{{R}_{2}}{{R}_{3}} \cdot ( \frac{{R}_{4}}{{R}_{2}} + \frac{{R}_{EXT}}{{R}_{2}} ) + 1 ]} \cdot Δ R + Δ {V}_{BG} + Δ {N}_{1} & ( 6 )\end{matrix}$$

Here, ε will be considered. Although ε is expressed as the sum of squares of ΔR, ΔV_{BG}, and ΔN₁, when considering the relative magnitudes, ΔV_{BG} and ΔN₁ are 2 to 3%, while ΔR which is the variation ratio of the resistance values of each resistor is 12 to 15%. However, ΔV_{BG} and ΔN₁ directly affect ε, but ΔR has a coefficient. This coefficient can be described by three variables of R₃/R₂, R₄/R₂ and R_{EXT}/R₂ normalized by R₂.

For the sake of simplicity, when it is assumed that R₄₌₀, the above Equation (6) can be simplified to the following Equation (7).

$$\begin{matrix}[ Equation 7 ] & \\ ε ( {R}_{4} = 0 ) = - \frac{\frac{{R}_{EXT}}{{R}_{2}}}{[ ( 1 + \frac{{R}_{2}}{{R}_{3}} ) \frac{{R}_{EXT}}{{R}_{2}} + 1 ] ( \frac{{R}_{2}}{{R}_{3}} \cdot \frac{{R}_{EXT}}{{R}_{2}} + 1 )} \cdot Δ R + Δ {V}_{BG} + Δ {N}_{1} & ( 7 )\end{matrix}$$

From the above Equation (7), it can be understood that ε can be described by two variables of R₃/R₂ and R_{EXT}/R₂. In the above Equation (7), the more important point is that when R_{EXT}/R₂=0 and R_{EXT}/R₂=∞, the coefficient of ΔR becomes zero and is independent of ε. The threshold voltage V_{TH} at this time is calculated from the above Equation (5) as given by the following Equation (8).

$$\begin{matrix}[ Equation 8 ] & \\ {V}_{TH} \approx \{ \begin{matrix}\frac{{N}_{1} {V}_{BG} {R}_{2}}{{R}_{1}} \cdot ( 1 + Δ {V}_{BG} + Δ {N}_{1} ) & : {R}_{EXT} = 0 \\ \frac{{N}_{1} {V}_{BG} {R}_{2}}{{R}_{1}} ( 1 + \frac{{R}_{3}}{{R}_{2}} ) \cdot ( 1 + Δ {V}_{BG} + Δ {N}_{1} ) & : {R}_{EXT} = ∞\end{matrix} & ( 8 )\end{matrix}$$

From the above Equation (8), it can be understood that when the resistance value R_{EXT} of the external resistor 6 is zero or infinity, the threshold voltage V_{TH} can be adjusted without affecting ΔR. Next, ε is calculated when R_{EXT}/R₂ is a finite value. From the above Equation (7), ε can be described by two variables of R₃/R₂ and R_{EXT}/R₂, and from the above Equation (8), the threshold voltage V_{TH} can be adjusted by R_{EXT}/R₂. Therefore, this problem comes down to a question of what R₃/R₂ should be selected to minimize ε. Now, the following Equation (9) is obtained by differentiating Equation (7) with respect to R_{EXT}.

$$\begin{matrix}[ Equation 9 ] & \\ \frac{d ε ( {R}_{4} = 0 )}{{dR}_{EXT}} = \frac{1}{{R}_{2}} \cdot \frac{{( \frac{{R}_{EXT}}{{R}_{2}} )}^{2} ( \frac{{R}_{2}}{{R}_{3}} ) ( 1 + \frac{{R}_{2}}{{R}_{3}} ) - 1}{{{[ ( \frac{{R}_{EXT}}{{R}_{2}} ) ( \frac{{R}_{2}}{{R}_{3}} ) + 1 ]}^{2} [ ( \frac{{R}_{EXT}}{{R}_{2}} ) ( 1 + \frac{{R}_{2}}{{R}_{3}} ) + 1 ]}^{2}} \cdot Δ R & ( 9 )\end{matrix}$$

Under a condition that the above Equation (9) is zero, ε indicates a maximum or minimum value, and therefore under a condition expressed by the following Equation (10), ε becomes a maximum or minimum value.

$$\begin{matrix}[ Equation 10 ] & \\ \frac{{R}_{EXT}}{{R}_{2}} = \frac{{R}_{3}}{{R}_{2}} \frac{1}{\sqrt{1 + \frac{{R}_{3}}{{R}_{2}}}} & ( 10 )\end{matrix}$$

The maximum or minimum value of ε can be calculated by substituting the above Equation (10) into the above Equation (7). The maximum value EMAX of ε is expressed by the following Equation (11).

$$\begin{matrix}[ Equation 11 ] & \\ {ε}_{MAX} ( {R}_{4} = 0 ) = - \frac{\frac{{R}_{3}}{{R}_{2}} \sqrt{1 + \frac{{R}_{3}}{{R}_{2}}}}{( 1 + \frac{{R}_{3}}{{R}_{2}} + \sqrt{1 + \frac{{R}_{3}}{{R}_{2}}} ) ( 1 + \sqrt{1 + \frac{{R}_{3}}{{R}_{2}}} )} \cdot Δ R + Δ {V}_{BG} + Δ {N}_{1} & ( 11 )\end{matrix}$$

As can be understood from the above Equation (11), since EMAX is a monotone increasing function of R₃/R₂, the coefficient of ΔR becomes small by setting R₃/R₂ to be small, and the effect of ΔR on ε can be reduced. On the other hand, as can be understood from the above Equation (8), when R₃/R₂ is set to be small, a variation range of V_{TH} due to RENT becomes narrow. Therefore, an optimal design can be achieved by determining the variation range of the threshold voltage V_{TH} using Equation (8) and selecting the minimum R₃/R₂ within the variation range.

As an example, a case in which the variation range of the threshold voltage V_{TH} due to the resistance value REST of the external resistor 6 is determined to be within a range from 6 [V] to 10 [V] is considered. From the above Equation (8), a relationship between the threshold voltage V_{TH} and R₃/R₂ is expressed by the following Equation (12).

$$\begin{matrix}[ Equation 12 ] & \\ \frac{{R}_{3}}{{R}_{2}} = \frac{{V}_{TH ( MAX )}}{{V}_{TH ( MIN )}} - 1 & ( 12 )\end{matrix}$$

When the variation range of the threshold voltage V_{TH} is determined to be within the range from 6 [V] to 10 [V], from the above Equation (12), R₃/R₂=⅔. Furthermore, When V_{BG}=1.2 [V] and N₁=2, R₂/R₁=2.5 according to Equation (8). When R₂=60 [kΩ], R₁=24 [kΩ] and R₃=40 [kΩ].

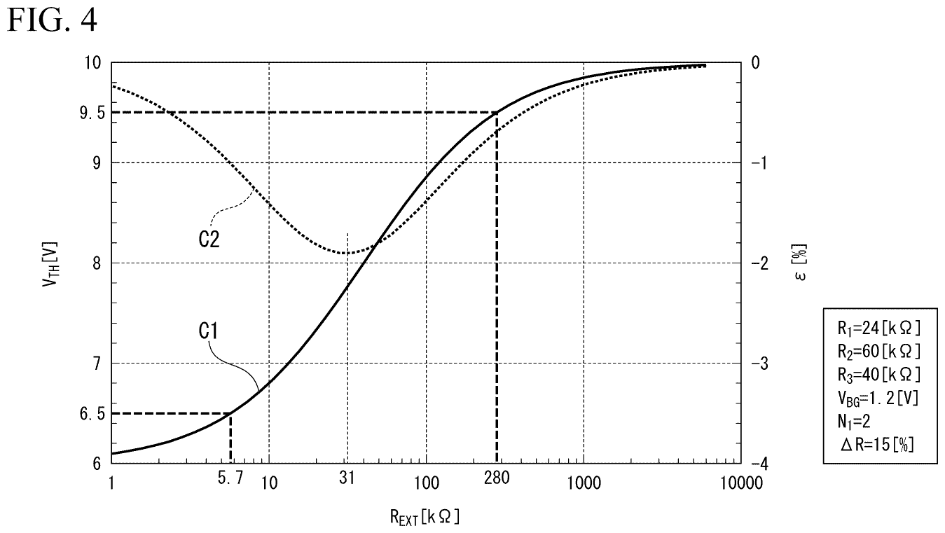

FIG. 4 is a graph showing results of calculating the threshold voltage V_{TH} with respect to the resistance value R_{EXT} of the external resistor 6 and the variation ratio ε of the threshold voltage V_{TH} with respect to the resistance value R_{EXT} of the external resistor 6, assuming R₁=24 [kΩ], R₂=60 [kΩ], R₃=40 [kΩ], V_{BG}=1.2 [V], N₁=2, and ΔR=15 [%]. In FIG. 4, a curve C1 expressed by a solid line indicates the threshold voltage V_{TH}, and a curve C2 expressed by a dashed line indicates the variation ratio ε of the threshold voltage V_{TH}.

When the power element SW is an IGBT or a Si-MOSFET, the threshold voltage V_{TH} is often set to about 6.5 [V]. When the power element SW is a SiC-MOSFET, the threshold voltage V_{TH} is often set to about 9.5 [V]. As shown in FIG. 4, when the resistance value R_{EXT} of the external resistor 6 is 5.7 [kΩ], the threshold voltage V_{TH} is 6.5 [V]. When the resistance value REST of the external threshold voltage resistor 6 is 280 [kΩ], the threshold voltage V_{TH} is 9.5 [V]. In this way, by simply changing the resistance value R_{EXT} of the external resistor 6, the threshold voltage V_{TH} can be adjusted to a voltage value required according to the type of power element SW. When the resistance value R_{EXT} of the external resistor 6 is 31 [kΩ], the variation ratio ε of the threshold voltage V_{TH} reaches a maximum value (about 1.9 [%]), but it can be understood that it is suppressed to about ⅛ of the variation ratio ΔR (15 [%]) of each of the resistors.

Also, as shown in FIG. 4, the threshold voltage V_{TH} can be adjusted within a range of 6 [V] to 10 [V] by changing the resistance value R_{EXT} of the external resistor 6. For example, when the power element SW is an IGBT or a Si-MOSFET, the threshold voltage V_{TH} can be set to 6 [V] or 7 [V]. When the power element SW is a SiC-MOSFET, the threshold voltage V_{TH} can be set to 9 [V] or 10 [V]. Thus, various power elements can be accommodated without changing the capacitance C_{BLK} of the capacitor 5.

The threshold voltage adjustment circuit 10 of this embodiment includes the reference current circuit 20 that outputs a reference current I_{REF}, and the trans-impedance circuit 30 that has a plurality of resistors and outputs the threshold voltage V_{TH} expressed as a function of the reference current I_{REF} and the combined resistance RT of the plurality of resistors and the external resistor 6. According to the threshold voltage adjustment circuit 10, the threshold voltage V_{TH} can be easily adjusted by a simple method of simply changing the resistance value R_{EXT} of the external resistor 6.

According to this embodiment, the influence of the variation ratio ΔR of the resistance value of each of the resistors with respect to the variation ratio ε of the threshold voltage V_{TH} can be minimized. In other words, since it is possible to curb the threshold voltage V_{TH} fluctuating due to manufacturing deviations in the resistance value of each of the resistors, the threshold voltage V_{TH} close to a required voltage value can be stably obtained.

As already explained, in order to accommodate various types of power elements SW (which have individual differences) and to resolve the trade-off between the speeding-up of the overcurrent detection operation and the improvement of the noise resistance, the value of the threshold voltage V_{TH} needs to be adjusted to various values. According to the semiconductor integrated circuit 1 of this embodiment, since the threshold voltage adjustment circuit 10 is provided that can easily adjust the threshold voltage V_{TH} to various values by a simple method of simply changing the resistance value REST of the external resistor 6, various types of power elements SW can be accommodated, and both the speeding-up of the overcurrent detection operation and the improvement of the noise resistance can be achieved.

In the semiconductor integrated circuit 1 of this embodiment, the first output buffer 13 outputs a gate drive signal that changes between the ground potential V_{GND} and the power supply potential V_{CC2} in synchronization with a timing signal. The overcurrent detection circuit 14 controls the first output buffer 13 so that a gate drive signal having the ground potential V_{GND} is output, after the output signal of the comparator 11 changes from a low level to a high level. According to this embodiment, when an overcurrent occurs in the power element SW (during an abnormality), the power element SW is reliably and forcibly switched to the OFF state, and thus the occurrence of failures and the like due to the overcurrent can be prevented.

In this embodiment, although the first current mirror circuit 31 is exemplified with the power supply terminal P3 as a reference, the first current mirror circuit 31 may be configured of a circuit that uses an internal power supply as a reference. Further, in this embodiment, although the first voltage controlled current source 22 configured of the operational amplifier 22a, the resistor 22b, and the MOSFET element 22c is exemplified, as long as the circuit has input and output characteristics equivalent to those of the first voltage controlled current source 22, the circuit configuration of the first voltage controlled current source 22 is not limited to the configuration of this embodiment. Although not shown in FIG. 3, it is desirable to arrange an ESD protection element at an appropriate position inside the threshold voltage adjustment circuit 10.

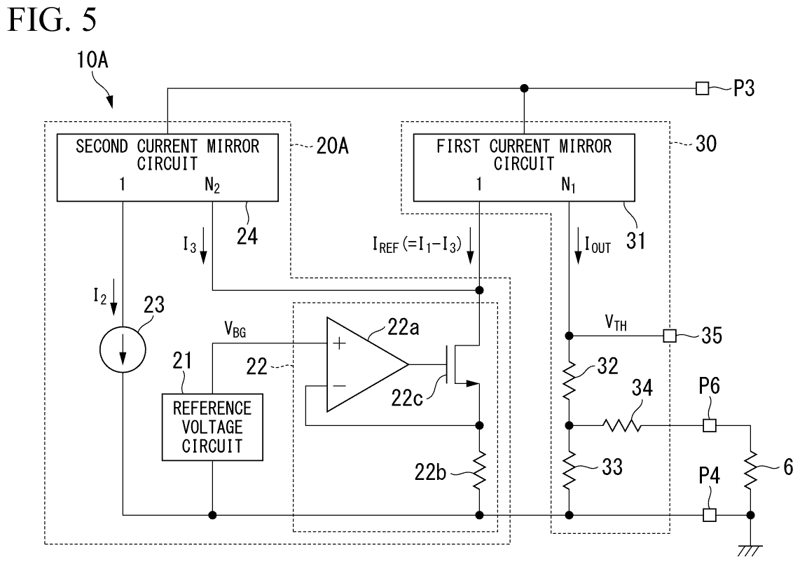

FIG. 5 is a circuit diagram showing a configuration of a threshold voltage adjustment circuit 10A which is a first modified example of the threshold voltage adjustment circuit 10. In the following description, among the components of the threshold voltage adjustment circuit 10A, the same components as those of the threshold voltage adjustment circuit 10 are designated by the same reference numerals, and the description thereof will be omitted or simplified.

As shown in FIG. 5, the threshold voltage adjustment circuit 10A includes a reference current circuit 20A and a trans-impedance circuit 30. The reference current circuit 20A is the same as the reference current circuit 20 in that it outputs a reference current I_{REF} but has a different circuit configuration from the reference current circuit 20. The reference current circuit 20A includes a reference voltage circuit 21, a first voltage controlled current source 22, a proportional-to-absolute temperature (PTAT) current source 23, and a second current mirror circuit 24.

The PTAT current source 23 is electrically connected to both the second current mirror circuit 24 and the ground terminal P4. The PTAT current source 23 outputs a second current I₂ proportional to the absolute temperature. The second current mirror circuit 24 is electrically connected to the power supply terminal P3. An input terminal of the second current mirror circuit 24 is electrically connected to the PTAT current source 23. The second current mirror circuit 24 receives the second current I₂ as an input, and outputs a third current I₃ which is a current that is a multiple of the second current I₂. For example, the second current mirror circuit 24 outputs the third current I₃ that is N₂ times the second current I₂, where N₂ is a current mirror ratio.

An output terminal of the second current mirror circuit 24 is electrically connected to a drain of the MOSFET element 22c of the first voltage controlled current source 22 and an input terminal of the first current mirror circuit 31 of the trans-impedance circuit 30. That is, the reference current circuit 20A outputs a current expressed by a difference between the first current I₁ output from the first voltage controlled current source 22 and the third current I₃ output from the second current mirror circuit 24 as the reference current I_{REF}. In other words, the reference current I_{REF} expressed by the difference between the first current I₁ and the third current I₃ is input to the first current mirror circuit 31 of the trans-impedance circuit 30. The first current I₁ is greater than the third current I₃.

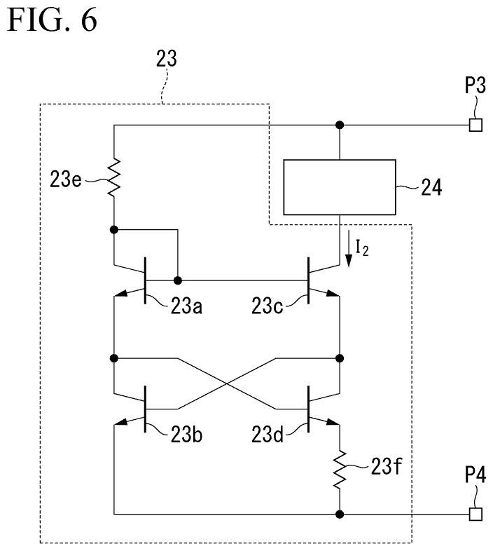

FIG. 6 is a circuit diagram showing an example of a configuration of the PTAT current source 23. As shown in FIG. 6, the PTAT current source 23 includes four transistors 23a, 23b, 23c, and 23d, and two resistors 23e and 23f. For example, the transistors 23a, 23b, 23c and 23d are NPN type bipolar transistors.

A collector of the transistor 23a is electrically connected to the power supply terminal P3 via the resistor 23e. A base of the transistor 23a is electrically connected to each of a collector of the transistor 23a and a base of the transistor 23c. A collector of the transistor 23b is electrically connected to each of an emitter of the transistor 23a and a base of the transistor 23d. A collector of the transistor 23d is electrically connected to each of an emitter of the transistor 23c and a base of the transistor 23b. An emitter of the transistor 23b is electrically connected to the ground terminal P4.

A collector of the transistor 23c is electrically connected to the input terminal of the second current mirror circuit 24. An emitter of the transistor 23d is electrically connected to the ground terminal P4 via the resistor 23f. A current flowing from the collector of the transistor 23c to the ground terminal P4 is the second current I₂.

The second current I₂ output from the PTAT current source 23 is expressed by the following Equation (13). In the following Equation (13), V_{T} is a thermal voltage, k is a size ratio between the transistors 23b and 23d, and R₅ is a resistance value of the resistor 23f. A resistance value of the resistor 23e does not affect the second current I₂. Therefore, a resistive element having a sheet resistance different from the other resistors 23f, 22b, 32, 33, and 34 may be used as the resistor 23e.

$$\begin{matrix}[ Equation 13 ] & \\ {I}_{2} = \frac{{V}_{T} ln ( k )}{{R}_{5}} \cdot \frac{1}{1 + Δ R} & ( 13 )\end{matrix}$$

As expressed by the following Equation (14), the reference current I_{REF} output from the reference current circuit 20A is expressed as a difference between the first current I₁ output from the first voltage controlled current source 22 and the third current I₃ output from the second current mirror circuit 24.

$$[ Equation 14 ]$$

$${I}_{REF} = {I}_{1} - {I}_{3} = {I}_{1} - {N}_{2} \cdot {I}_{2} \qquad ( 14 )$$

As expressed by the following Equation (15), a current I_{OUT} output from the first current mirror circuit 31 of the trans-impedance circuit 30 is a current that is N₁ times the reference current I_{REF} expressed by the Equation (14).

$$[ Equation 15 ]$$

$${I}_{OUT} = {N}_{1} \cdot {I}_{REF} = {N}_{1} \cdot ( {I}_{1} - {N}_{2} . \cdot {I}_{2} ) \qquad ( 15 )$$

When Equation (3) is substituted into Equation (15) as the first current I₁ output from the first voltage controlled current source 22, and Equation (13) is substituted into Equation (15) as the second current I₂ output from the PTAT current source 23, the following Equation (16) is obtained.

$$[ Equation 16 ]$$

$${I}_{OUT} = \frac{{N}_{1} {V}_{BG}}{{R}_{1}} \cdot \frac{1 + Δ {V}_{BG}}{1 + Δ R} - \frac{{N}_{1} {N}_{2} {V}_{T} ln ( k )}{{R}_{5}} \cdot \frac{1}{1 + Δ R} \qquad ( 16 )$$

The threshold voltage V_{TH} output from the trans-impedance circuit 30 is calculated by multiplying the output current I_{OUT} of the first current mirror circuit 31 by a combined resistance RT of the resistors 32, 33 and 34 and the external resistor 6. Assuming that ΔR<<1, ΔN₁<<1, ΔN₂<<1, and ΔV_{BG}<<1, the threshold voltage V_{TH} is expressed by the following Equation (17). In the following Equation (17), R₂ is a resistance value of the resistor 32, R₃ is a resistance value of the resistor 33, R₄ is a resistance value of the resistor 34, and R_{EXT} is a resistance value of the external resistor 6.

$$[ Equation 17 ]$$

$${V}_{TH} {N}_{1} {R}_{2} \cdot [ 1 + \frac{\frac{{R}_{4}}{{R}_{2}} + \frac{{R}_{EXT}}{{R}_{2}}}{1 + \frac{{R}_{2}}{{R}_{3}} \cdot ( \frac{{R}_{4}}{{R}_{2}} + \frac{{R}_{EXT}}{{R}_{2}} )} ] \cdot [ \frac{{V}_{BC}}{{R}_{1}} \cdot ( 1 + ε ) - \frac{{N}_{2} {V}_{T} ln ( k )}{{R}_{5}} \cdot ( 1 + {ε}_{T} ) ] \qquad ( 17 )$$

In the above Equation (17), ET is expressed by the following Equation (18).

$$[ Equation 18 ]$$

$${ε}_{T} - \frac{\frac{{R}_{EXT}}{{R}_{2}} ( 1 + \frac{{R}_{4}}{{R}_{2}} \cdot \frac{{R}_{2}}{{R}_{3}} )}{[ ( 1 + \frac{{R}_{2}}{{R}_{3}} ) ( \frac{{R}_{4}}{{R}_{2}} + \frac{{R}_{EXT}}{{R}_{2}} ) + 1 ] [ \frac{{R}_{2}}{{R}_{3}} \cdot ( \frac{{R}_{4}}{{R}_{2}} + \frac{{R}_{EXT}}{{R}_{2}} ) + 1 ]} ] \cdot Δ R + Δ {N}_{1} + Δ {N}_{2} \qquad ( 18 )$$

For the sake of simplicity, assuming that R₄=0, the above Equation (18) can be simplified to the following Equation (19).

$$[ Equation 19 ]$$

$${ε}_{T} ( {R}_{4} = 0 ) = - \frac{\frac{{R}_{EXT}}{{R}_{2}}}{[ ( 1 + \frac{{R}_{2}}{{R}_{3}} ) \frac{{R}_{EXT}}{{R}_{2}} + 1 ] ( \frac{{R}_{2}}{{R}_{3}} \cdot \frac{{R}_{EXT}}{{R}_{2}} + 1 )} \cdot Δ R + Δ {N}_{1} + Δ {N}_{2} \qquad ( 19 )$$

From the above Equation (19), similarly to the threshold voltage adjustment circuit 10, since the fluctuation of the threshold voltage V_{TH} due to the variation ratio ΔR of the resistance value of each of the resistors is curbed, it is possible to impart any negative temperature characteristics to the threshold voltage V_{TH} by changing a ratio between the first current I₁ and the second current I₂. When T_{C1} is defined as a temperature coefficient, the above Equation (17) can be written as the following Equation (20).

$$[ Equation 20 ]$$

$${V}_{TH} \frac{{N}_{1} {V}_{BG} {R}_{2}}{{R}_{1}} \cdot [ 1 + \frac{\frac{{R}_{4}}{{R}_{2}} + \frac{{R}_{EXT}}{{R}_{2}}}{1 + \frac{{R}_{2}}{{R}_{3}} \cdot ( \frac{{R}_{4}}{{R}_{2}} + \frac{{R}_{EXT}}{{R}_{2}} )} ] \cdot [ 1 + {T}_{C 1} + ε + {T}_{C 1} {ε}_{T} ] \qquad ( 20 )$$

In the above Equation (20), the temperature coefficient T_{C1} is expressed by the following Equation (21). As can be understood from the following Equation (21), the threshold voltage adjustment circuit 10A can impart any negative temperature characteristics to the threshold voltage V_{TH}.

$$[ Equation 21 ]$$

$${T}_{C 1} = - \frac{{N}_{2} {V}_{T} ln ( k )}{{V}_{BG}} \cdot \frac{{R}_{1}}{{R}_{5}} \qquad ( 21 )$$

According to the threshold voltage adjustment circuit 10A having such a configuration, in addition to being able to easily adjust the threshold voltage V_{TH} by the simple method of simply changing the resistance value R_{EXT} of the external resistor 6, it is also possible to impart any negative temperature characteristics to the threshold voltage V_{TH}. Generally, the threshold voltage of the power element SW such as an IGBT, a Si-MOSFET, or a SiC-MOSFET has negative temperature characteristics.

Therefore, overcurrent detection sensitivity at high temperature can be improved by imparting the negative temperature characteristics to the threshold voltage V_{TH} output from the threshold voltage adjustment circuit 10A to the comparator 11, and as a result, safer overcurrent protection operation can be achieved.

In the first modified example, although the second current mirror circuit 24 is exemplified with the power supply terminal P3 as a reference, the second current mirror circuit 24 may be configured of a circuit that uses an internal power supply as a reference. In addition, in the first modified example, the PTAT current source 23 configured of four NPN bipolar transistors and two resistors is exemplified, but the circuit configuration of the PTAT current source 23 is not limited to the configuration of the first modified example as long as the circuit has input and output characteristics equivalent to those of the PTAT current source 23. Although not shown in FIG. 5, it is desirable to arrange an ESD protection element at an appropriate position inside the threshold voltage adjustment circuit 10A.

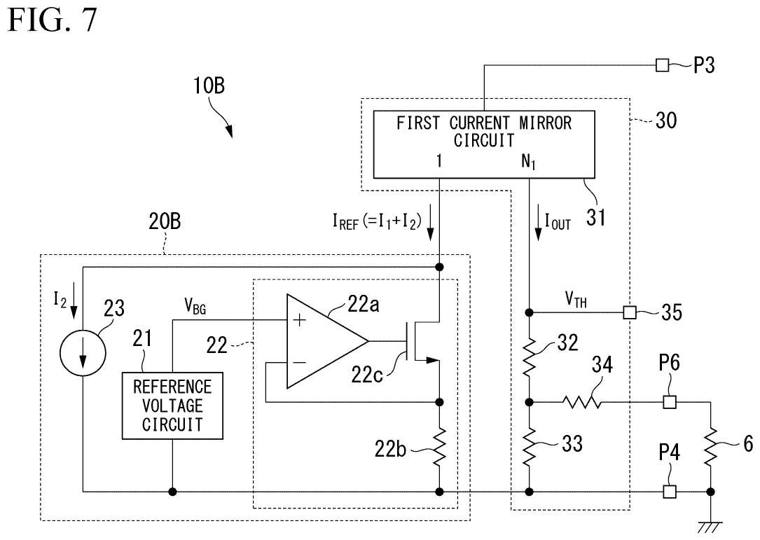

FIG. 7 is a circuit diagram showing a configuration of a threshold voltage adjustment circuit 10B which is a second modified example of the threshold voltage adjustment circuit 10. In the following description, among the components of the threshold voltage adjustment circuit 10B, the same components as those of the threshold voltage adjustment circuit 10A are designated by the same reference numerals, and the description thereof will be omitted or simplified.

As shown in FIG. 7, the threshold voltage adjustment circuit 10B includes a reference current circuit 20B and a trans-impedance circuit 30. The reference current circuit 20B is the same as the reference current circuit 20A in that it outputs the reference current I_{REF} but has a different circuit configuration from the reference current circuit 20A. The reference current circuit 20B includes a reference voltage circuit 21, a first voltage controlled current source 22, and a PTAT current source.

The PTAT current source 23 is electrically connected to each of a drain of the MOSFET element 22c and the ground terminal P4. The PTAT current source 23 outputs a second current I₂ that is proportional to the absolute temperature. That is, the reference current circuit 20B outputs a current expressed by the sum of the first current I₁ output from the first voltage controlled current source 22 and the second current I₂ output from the PTAT current source 23 as the reference current I_{REF}. In other words, the reference current I_{REF} expressed by the sum of the first current I₁ and the second current I₂ is input to the first current mirror circuit 31 of the trans-impedance circuit 30. In this case, the current I_{OUT} output from the first current mirror circuit 31 is expressed by the following Equation (22).

$$[ Equation 22 ]$$

$${I}_{OUT} = {N}_{1} \cdot {I}_{REF} = {N}_{1} . ( {I}_{1} + {I}_{2} ) \qquad ( 22 )$$

When Equation (3) is substituted into equation (22) as the first current I₁ output from the first voltage controlled current source 22, and Equation (13) is substituted into Equation (22) as the second current I₂ output from the PTAT current source 23, the following Equation (23) is obtained.

$$[ Equation 23 ]$$

$${l}_{OUT} = \frac{{N}_{1} {V}_{BG}}{{R}_{1}} \cdot \frac{1 + Δ {V}_{BG}}{1 + Δ R} + \frac{{N}_{1} {V}_{T} ln ( k )}{{R}_{5}} \cdot \frac{1}{1 + Δ R} \qquad ( 23 )$$

The threshold voltage V_{TH} output from the trans-impedance circuit 30 is calculated by multiplying the output current I_{OUT} of the first current mirror circuit 31 by the combined resistance RT of the resistors 32, 33 and 34 and the external resistor 6. Assuming that ΔR<<1, ΔN₁<<1, and ΔV_{BG}<<1, the threshold voltage V_{TH} is expressed by the following Equation (24). In the following Equation (24), R₂ is a resistance value of resistor 32, R₃ is a resistance value of resistor 33, R₄ is a resistance value of resistor 34, and R_{EXT} is a resistance value of external resistor 6.

$$[ Equation 24 ]$$

$${V}_{TH} {N}_{1} {R}_{2} \cdot [ 1 + \frac{\frac{{R}_{4}}{{R}_{2}} + \frac{{R}_{EXT}}{{R}_{2}}}{1 + \frac{{R}_{2}}{{R}_{3}} \cdot ( \frac{{R}_{4}}{{R}_{2}} + \frac{{R}_{EXT}}{{R}_{2}} )} ] \cdot [ \frac{{V}_{BC}}{{R}_{1}} \cdot ( 1 + ε ) - \frac{{V}_{T} ln ( k )}{{R}_{5}} \cdot ( 1 + {ε}_{T} ) ] \qquad ( 24 )$$

In the above Equation (24), ET is expressed by the following Equation (25).

$$[ Equation 25 ]$$

$${ε}_{T} - \frac{\frac{{R}_{EXT}}{{R}_{2}} ( 1 + \frac{{R}_{4}}{{R}_{2}} \cdot \frac{{R}_{2}}{{R}_{3}} )}{[ ( 1 + \frac{{R}_{2}}{{R}_{3}} ) ( \frac{{R}_{4}}{{R}_{2}} + \frac{{R}_{EXT}}{{R}_{2}} ) + 1 ] [ \frac{{R}_{2}}{{R}_{3}} \cdot ( \frac{{R}_{4}}{{R}_{2}} + \frac{{R}_{EXT}}{{R}_{2}} ) + 1 ]} \cdot Δ R + Δ {N}_{1} \qquad ( 25 )$$

When the temperature coefficient T_{C1} is defined in the same manner as in the first modified example, the temperature coefficient T_{C1} in the second modified example is expressed by the following Equation (26). As can be understood from the following Equation (26), the threshold voltage adjustment circuit 10B can impart any positive temperature characteristics to the threshold voltage V_{TH}.

$$[ Equation 26 ]$$

$${T}_{C 1} = \frac{{V}_{T} ln ( k )}{{V}_{BG}} \cdot \frac{{R}_{1}}{{R}_{5}} \qquad ( 26 )$$

According to the threshold voltage adjustment circuit 10B having such a configuration, in addition to being able to easily adjust the threshold voltage V_{TH} by the simple method of simply changing the resistance value R_{EXT} of the external resistor 6, it is also possible to impart any positive temperature characteristics to the threshold voltage V_{TH}. For example, a positive temperature coefficient (PTC) thermistor may be used to protect a three-phase induction motor from overheating. The PCT thermistor is a device of which a resistance value increases rapidly when it reaches or exceeds the Curie temperature, and I-V characteristics thereof depend on an ambient temperature. That is, the voltage at which a trip current occurs has the positive temperature characteristics with respect to the ambient temperature. For this reason, it is desirable that the threshold voltage of the circuit that detects a state of the PCT thermistor has the positive temperature characteristics. The threshold voltage adjustment circuit 10B of the second modified example is particularly suitable for the above-described application example.

As in the first modified example, the circuit configuration of the PTAT current source 23 in the second modified example is not limited to the configuration in the first modified example. Although not shown in FIG. 7, it is desirable to arrange an ESD protection element at an appropriate position inside the threshold voltage adjustment circuit 10B.

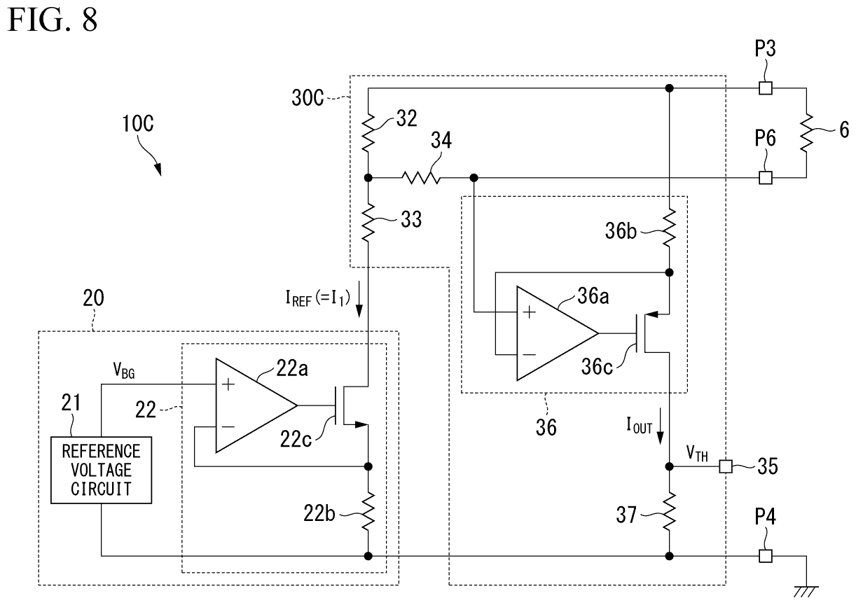

FIG. 8 is a circuit diagram showing a configuration of a threshold voltage adjustment circuit 10C which is a third modified example of the threshold voltage adjustment circuit 10. In the following description, among the components of the threshold voltage adjustment circuit 10C, the same components as those of the threshold voltage adjustment circuit 10 are designated by the same reference numerals, and the description thereof will be omitted or simplified.

As shown in FIG. 8, the threshold voltage adjustment circuit 10C includes a reference current circuit 20 and a trans-impedance circuit 30C. The trans-impedance circuit 30C is the same as the trans-impedance circuit 30 in that it outputs a threshold voltage V_{TH} that changes according to the resistance value of the external resistor 6 but has a different circuit configuration from the trans-impedance circuit 30. The trans-impedance circuit 30C includes a resistor 32, a resistor 33, a resistor 34, a threshold voltage output terminal 35, a second voltage controlled current source 36, and a resistor 37. In the example shown in FIG. 8, the external resistor 6 is connected between the resistor connection terminal P6 and the power supply terminal P3.

One end of the resistor 32 is electrically connected to one end of the external resistor 6 via the power supply terminal P3. The other end of the resistor 32 is electrically connected to the other end of the external resistor 6 via the resistor 34 and the resistor connection terminal P6. One end of the resistor 33 is electrically connected to the other end of the resistor 32. The other end of the resistor 33 is electrically connected to the output terminal of the first voltage controlled current source 22 of the reference current circuit 20. That is, the other end of the resistor 33 is electrically connected to a drain of the MOSFET element 22c of the first voltage controlled current source 22.

One end of the resistor 34 is electrically connected to a connection point between the resistor 32 and the resistor 33. The other end of the resistor 34 is electrically connected to the other end of the external resistor 6 via the resistor connection terminal P6. The resistor 34 is not essential, and the trans-impedance circuit 30C may include only the resistors 32 and 33 as a plurality of resistors.

The second voltage controlled current source 36 outputs a current I_{OUT} proportional to a voltage of the resistor connection terminal P6. The second voltage controlled current source 36 includes an operational amplifier 36a, a resistor 36b, and a MOSFET element 36c. For example, the MOSFET element 36c is a P-channel type MOSFET. A non-inverting input terminal of the operational amplifier 36a is electrically connected to the resistor connection terminal P6. That is, the voltage of the resistor connection terminal P6 is input to the non-inverting input terminal of the operational amplifier 36a. An inverting input terminal of the operational amplifier 36a is electrically connected to a source of the MOSFET element 36c. An output terminal of the operational amplifier 36a is electrically connected to a gate of the MOSFET element 36c.

One end of the resistor 36b is electrically connected to the power supply terminal P3 to which a power supply potential V_{CC2} is applied. The other end of the resistor 36b is electrically connected to a source of the MOSFET element 36c. One end of the resistor 37 is electrically connected to an output terminal of the second voltage controlled current source 36. Specifically, one end of the resistor 37 is electrically connected to the drain of the MOSFET element 36c. The other end of the resistor 37 is electrically connected to the ground terminal P4. A current flowing from the drain of the MOSFET element 36c to the resistor 37 is the output current I_{OUT} of the second voltage controlled current source 36. The threshold voltage output terminal 35 is a terminal that outputs the threshold voltage V_{TH} and is electrically connected to one end of the resistor 37. In the third modified example, the resistor 32 is an example of a first resistor, the resistor 33 is an example of a second resistor, and the resistor 37 is an example of a third resistor.

The threshold voltage V_{TH} output from the trans-impedance circuit 30C is expressed by the following Equation (27). In the following Equation (27), R₂ is a resistance value of the resistor 32, R₃ is a resistance value of the resistor 33, R₄ is a resistance value of the resistor 34, R₇ is a resistance value of the resistor 36b, R₈ is a resistance value of the resistor 37, and R_{EXT} is a resistance value of the external resistor 6.

$$[ Equation 27 ]$$

$${V}_{TH} \frac{{V}_{BG} {R}_{2}}{{R}_{1}} \cdot \frac{{R}_{8}}{{R}_{7}} \cdot [ 1 + \frac{\frac{{R}_{4}}{{R}_{2}} + \frac{{R}_{EXT}}{{R}_{2}}}{1 + \frac{{R}_{2}}{{R}_{3}} \cdot ( \frac{{R}_{4}}{{R}_{2}} + \frac{{R}_{EXT}}{{R}_{2}} )} ] \cdot ( 1 + ε ) \qquad ( 27 )$$

As can be understood by comparing Equation (27) with Equation (5), in the third modified example, Equation (27) that expresses the threshold voltage V_{TH} is obtained by replacing N₁ in Equation (5) with R₅/R₇. In this way, it can be understood that the threshold voltage adjustment circuit 10C of the third modified example can provide the same effects as the threshold voltage adjustment circuit 10.

According to the threshold voltage adjustment circuit 10C of the third modified example, it is possible to obtain the same effects as those of the threshold voltage adjustment circuit 10. That is, according to the threshold voltage adjustment circuit 10C, the threshold voltage V_{TH} can be easily adjusted by a simple method of simply changing the resistance value R_{EXT} of the external resistor 6. Furthermore, the threshold voltage adjustment circuit 10C can minimize the influence of the variation ratio ΔR of the resistance value in each of the resistors with respect to the variation ratio ε of the threshold voltage V_{TH}.

In the third modified example, the second voltage controlled current source 36 configured of the operational amplifier 36a, the resistor 36b, and the MOSFET element 36c is exemplified, but the circuit configuration of the second voltage controlled current source 36 is not limited to that of the third modified example as long as the circuit has input and output characteristics equivalent to those of the second voltage controlled current source 36. Although not shown in FIG. 8, it is desirable to arrange an ESD protection element at an appropriate position inside the threshold voltage adjustment circuit 10C.

### Second Embodiment

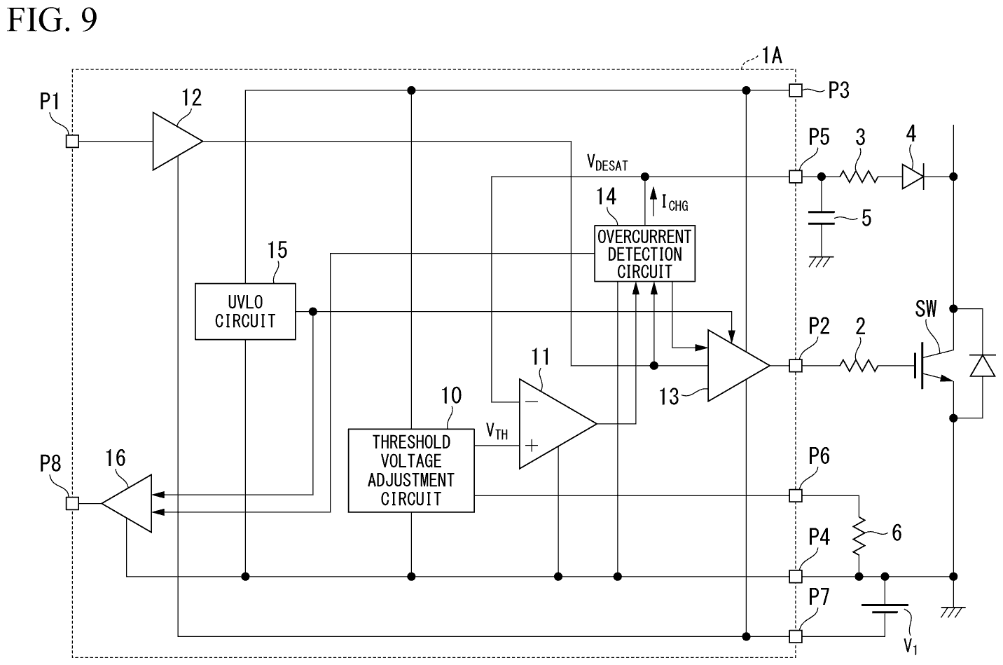

FIG. 9 is a circuit diagram showing a configuration of a semiconductor integrated circuit 1A according to a second embodiment. In the following description, among components described in the second embodiment, the components that are the same as those described in the first embodiment are given the same reference numerals, and description thereof will be omitted or simplified.

Like the semiconductor integrated circuit 1 of the first embodiment, a semiconductor integrated circuit 1A of the second embodiment includes an input terminal P1, an output terminal P2, a power supply terminal P3, a ground terminal P4, an overcurrent detection terminal P5, a resistor connection terminal P6, a threshold voltage adjustment circuit 10, a comparator 11, an input buffer 12, a first output buffer 13, and an overcurrent detection circuit 14. The semiconductor integrated circuit 1A further includes a negative power supply terminal P7, an abnormality notification terminal P8, an under voltage lock-out (ULVO) circuit 15, and a second output buffer 16.

In FIG. 9, the constant current source 14a, the switch 14b, and the control circuit 14c included in the overcurrent detection circuit 14 are omitted. Moreover, the semiconductor integrated circuit 1A may include, instead of the threshold voltage adjustment circuit 10, any one of the threshold voltage adjustment circuit 10A, the threshold voltage adjustment circuit 10B, and the threshold voltage adjustment circuit 10C.

The negative power supply terminal P7 is a terminal to which a negative power supply potential V_{EE} which is a negative potential with respect to the ground potential V_{GND}, is applied. For example, when a potential difference between the ground terminal P4 and the negative power supply terminal P7, that is, a potential difference between the ground potential V_{GND} and the negative power supply potential V_{EE} is V1, a voltage of the negative power supply terminal P7 with the ground potential V_{GND} as a reference is −V1. However, since a potential of a silicon substrate needs to be a minimum potential, a silicon substrate potential becomes V_{EE}. The abnormality notification terminal P8 is a terminal that outputs an abnormality notification signal for notifying occurrence of an abnormality. For example, the abnormality notification signal output from the abnormality notification terminal P8 during a normal operation is a third level signal. When an overcurrent flows through the power element SW or when an abnormality occurs in the power supply voltage, the abnormality notification signal becomes a fourth level. For example, the third level is a high level, and the fourth level is a low level.

The ULVO circuit 15 is electrically connected to each of the power supply terminal P3 and the ground terminal P4. The ULVO circuit 15 compares a power supply voltage with a predetermined value, and outputs a voltage determination signal indicating a comparison result to the first output buffer 13 and the second output buffer 16. The power supply voltage is a potential difference between the power supply terminal P3 and the ground terminal P4, that is, a potential difference between the power supply potential V_{CC2} and the ground potential V_{GND}.

For example, when the power supply voltage is equal to or higher than the predetermined value, the ULVO circuit 15 outputs a low-level voltage determination signal to the first output buffer 13 and the second output buffer 16. Furthermore, when the power supply voltage is lower than the predetermined value, the ULVO circuit 15 outputs a high-level voltage determination signal to the first output buffer 13 and the second output buffer 16. The case in which the power supply voltage is lower than the predetermined value is a case in which an abnormality occurs in the power supply voltage. In other words, when an abnormality occurs in the power supply voltage, the ULVO circuit 15 outputs the high-level voltage determination signal.

In the second embodiment, in addition to a timing signal output from the input buffer 12 and a first control signal output from the overcurrent detection circuit 14, the voltage determination signal output from the ULVO circuit 15 is input to the first output buffer 13. When both the first control signal and the voltage determination signal are at a low level, the first output buffer 13 generates a gate drive signal in synchronization with the timing signal input via the input circuit 12, and outputs the gate drive signal via the output terminal P2.

The first output buffer 13 outputs a gate drive signal that changes between the negative power supply potential V_{EE} and the power supply potential V_{CC2} in synchronization with the timing signal. When at least one of the first control signal and the voltage determination signal is at a high level, the first output buffer 13 outputs the gate drive signal having the negative power supply potential V_{EE}, regardless of the timing signal.

The voltage determination signal output from the ULVO circuit 15 and the second control signal output from the overcurrent detection circuit 14 are input to the second output buffer 16. An output terminal of the second output buffer 16 is electrically connected to the abnormality notification terminal P8. The second output buffer 16 generates an abnormality notification signal on the basis of the voltage determination signal and the second control signal, and outputs the abnormality notification signal via the abnormality notification terminal P8. For example, when at least one of the voltage determination signal and the second control signal is at a high level, the second output buffer 16 outputs a low-level abnormality notification signal. When both the voltage determination signal and the second control signal are at a low level, the second output buffer 16 outputs a high-level normality notification signal.

In the second embodiment, the overcurrent detection circuit 14 controls the first output buffer 13 so that a gate drive signal having the negative power supply potential V_{EE} is output after the output signal of the comparator 11 changes from a low level to a high level. The overcurrent detection circuit 14 controls the first output buffer 13 by outputting the first control signal to the first output buffer 13.

After the output signal of the comparator 11 changes from a low level to a high level, the overcurrent detection circuit 14 changes the first control signal from a low level to a high level. As described above, when the level of the first control signal is high, the first output buffer 13 outputs a gate drive signal having the negative power supply potential V_{EE} regardless of the timing signal.

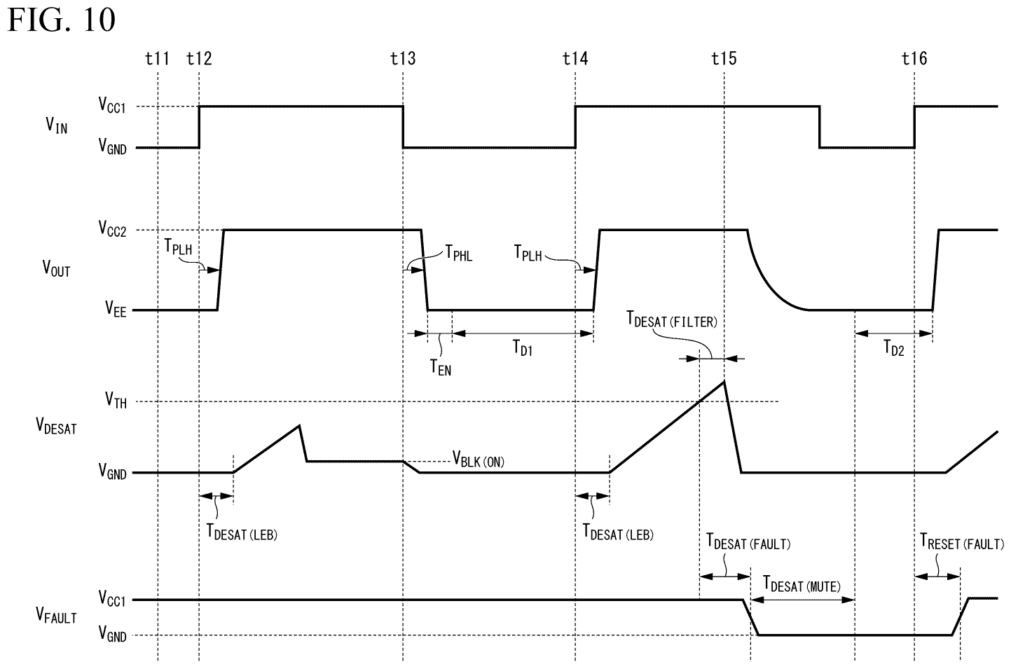

FIG. 10 is a timing chart showing a voltage waveform at each of terminals of the semiconductor integrated circuit 1A. Specifically, the timing chart of FIG. 10 shows waveforms of an input terminal voltage V_{IN}, an output terminal voltage V_{OUT}, a detection terminal voltage V_{DESAT}, and an abnormality notification terminal voltage V_{FAULT}.

The input terminal voltage V_{IN} is a voltage of the input terminal P1 with the ground potential V_{GND} as a reference. The input terminal voltage V_{IN} corresponds to a timing signal input to the input terminal P1. The output terminal voltage V_{OUT} is a voltage at the output terminal P2 with the negative power supply potential V_{EE} as a reference. The output terminal voltage V_{OUT} corresponds to the gate drive signal output from the output terminal P2. The detection terminal voltage V_{DESAT} is a voltage at the overcurrent detection terminal P5 with the ground potential V_{GND} as a reference. The abnormality notification terminal voltage V_{FAULT} is a voltage at the abnormality notification terminal P8 with the ground potential V_{GND} as a reference. The abnormality notification terminal voltage V_{FAULT} corresponds to the abnormality notification signal output from the abnormality notification terminal P8. In FIG. 10, V_{CC1} is a high-level potential of a digital signal such as the timing signal and the abnormality notification signal. V_{CC1} is lower than the power supply potential V_{CC2} applied to the power supply terminal P3.

As shown in FIG. 10, it is assumed that at a time t11, both the input terminal voltage V_{IN} corresponding to the timing signal and the detection terminal voltage V_{DESAT} are at a low level (V_{GND}). Since the detection terminal voltage V_{DESAT} is equal to or lower than the threshold voltage V_{TH}, the output signal of the comparator 11 is at a low level. At such time t11, since the output signal of the comparator 11 is at a low level, the control circuit 14c outputs a first control signal at a low level to the first output buffer 13. When the level of the first control signal is low, the first output buffer 13 generates a gate drive signal in synchronization with the timing signal. As a result, at the time t11, the output terminal voltage V_{OUT} corresponding to the gate drive signal is also in a low level (V_{EE}), and thus the power element SW is in the OFF state.

When the power element SW is in the OFF state, there is no need to detect an overcurrent in the power element SW. Therefore, in this case, the control circuit 14c may set the constant current source 14a to the disabled state and may set the switch 14b to the ON state or may set the switch 14b to the ON state while the constant current source 14a is in operation. As a result, the detection terminal voltage V_{DESAT} becomes substantially equal to the ground potential V_{GND}, and thus the charge is completely discharged from the capacitor 5.

At the time t11, since the output signal of the comparator 11 is at a low level, the control circuit 14c outputs a low-level second control signal to the second output buffer 16. It is also assumed that a low-level voltage determination signal is output from the ULVO circuit 15 to the second output buffer 16 at the time t11. At such time t11, the abnormality notification terminal voltage V_{FAULT} which corresponds to the abnormality notification signal output from the second output buffer 16 is at a high level (V_{CC1}).

At a time t12 after the time t11, when the input terminal voltage V_{IN} changes from a low level (V_{GND}) to a high level (V_{CC1}), after a predetermined propagation delay time T_{PLH} has elapsed, the output terminal voltage V_{OUT} also changes from a low level (V_{EE}) to a high level (V_{CC2}). As a result, the power element SW switches from the OFF state to the ON state.

When the power element SW is in the ON state, it is necessary to detect an overcurrent in the power element SW. Therefore, when the input terminal voltage V_{IN} changes to a high level (V_{CC1}) at the time t12, after a first standby time T_{DESAT(LEB)} has elapsed from the time t12, the control circuit 14c sets the constant current source 14a to the enabled state and sets the switch 14b to the OFF state. Alternatively, the control circuit 14c may set the constant current source 14a to the enabled state before the time t12, and then may set the switch 14b to the OFF state after the first standby time T_{DESAT(LEB)} has elapsed from the time t12. As a result, after the first standby time T_{DESAT(LEB)} has elapsed from the time t12, a detection current I_{CHG} is output from the overcurrent detection terminal P5.

However, even when the output terminal voltage V_{OUT} changes from a low level (V_{EE}) to a high level (V_{CC2}), the power element SW is not immediately in the ON state. That is, for a certain period of time after the output terminal voltage V_{OUT} changes to a high level (V_{CC2}), a collector terminal voltage of the power element SW is maintained in a high state, and the diode 4 is biased in the reverse direction. As a result, the detection current I_{CHG} flows to the capacitor 5, and thus the detection terminal voltage V_{DESAT} rises from the ground potential V_{GND}.

When the power device SW is completely in the ON state before the detection terminal voltage V_{DESAT} reaches the threshold voltage V_{TH}, the diode 4 is biased in the forward direction. As a result, the detection current I_{CHG} flows to the collector of the power element SW via the resistor 3 and the diode 4, and thus the detection terminal voltage V_{DESAT} falls. When a value of the detection terminal voltage V_{DESAT} reaches the steady-state voltage value V_{BLK(ON)}, the value of the detection terminal voltage V_{DESAT} is maintained at the steady-state voltage value V_{BLK(ON)} while the power element SW is in the ON state.

At a time t13 after the time t12, when the input terminal voltage V_{IN} changes from a high level (V_{CC1}) to a low level (V_{GND}), after a predetermined propagation delay time T_{PHL} has elapsed, the output terminal voltage V_{OUT} also changes from a high level (V_{CC2}) to a low level (V_{EE}). As a result, the power element SW switches from the ON state to the OFF state.

As described above, when the power element SW is in the OFF state, there is no need to detect an overcurrent in the power element SW. Therefore, when the input terminal voltage V_{IN} changes to a low level (V_{GND}) at the time t13, the control circuit 14c may set the constant current source 14a to the disabled state and may set the switch 14b to the ON state or may set the switch 14b to the ON state while the constant current source 14a is in operation. As a result, since the charge is completely discharged from the capacitor 5, the value of the detection terminal voltage V_{DESAT} falls from the steady-state voltage value V_{BLK(ON)} to the ground potential V_{GND}.

At a time t14 after the time t13, when the input terminal voltage V_{IN} changes from a low level (V_{GND}) to a high level (V_{CC1}), after a predetermined propagation delay time T_{PLH} has elapsed, the output terminal voltage V_{OUT} also changes from a low level (V_{EE}) to a high level (V_{CC2}). As a result, the power element SW switches from the OFF state to the ON state.

Similar to the time t12, when the input terminal voltage V_{IN} changes to a high level (V_{CC1}) at the time t14, after the first standby time T_{DESAT(LEB)} has elapsed from the time t14, the control circuit 14c sets the constant current source 14a to the enabled state and sets the switch 14b to the OFF state, or sets the switch 14b to the OFF state while the constant current source 14a is in operation. Here, when it is assumed that an overcurrent flows through the power element SW, the power element SW operates in a non-saturated state, and a collector-emitter voltage of the power element SW rises. As a result, since the diode 4 is biased in the reverse direction, and thus the detection current I_{CHG} flows through the capacitor 5, the detection terminal voltage V_{DESAT} rises from the ground potential V_{GND}.

When an overcurrent continues to flow through the power element SW, the detection terminal voltage V_{DESAT} continues to rise with the passage of time. When the detection terminal voltage V_{DESAT} exceeds the threshold voltage V_{TH}, the output signal of the comparator 11 changes from a low level to a high level.

At a time t15 when the detection terminal voltage V_{DESAT} exceeds the threshold voltage V_{TH}, that is, when the second standby time T_{DESAT(FILTER)} has elapsed from a point in time when the output signal of the comparator 11 changed from a low level to a high level, the control circuit 14c determines that an overcurrent has flowed through the power element SW, and changes the first control signal to be output to the first output buffer 13 from a low level to a high level. When the level of the first control signal is high, the output buffer 13 outputs a gate drive signal having the negative power supply potential V_{EE} regardless of the timing signal. Therefore, after the second standby time T_{DESAT(FILTER)} has elapsed from the time the detection terminal voltage V_{DESAT} exceeds the threshold voltage V_{TH}, the output terminal voltage V_{OUT} changes gradually from the high level (V_{CC2}) to the low level (V_{EE}). As a result, when an overcurrent flows through the power element SW, the power element SW is forcibly switched to the OFF state.

In addition, after the second standby time T_{DESAT(FILTER)} has elapsed from a point in time when the output signal of the comparator 11 changes from a low level to a high level, the control circuit 14c sets the constant current source 14a to the disabled state and sets the switch 14b to the ON state or sets the switch 14b to the ON state while the constant current source 14a is in operation. As a result, the charge is completely discharged from the capacitor 5, and thus the value of the detection terminal voltage V_{DESAT} quickly falls to the ground potential V_{GND}.

Furthermore, after a third standby time T_{DESAT(FAULT)} has elapsed from a point in time when the output signal of the comparator 11 changed from a low level to a high level, the control circuit 14c changes the second control signal to be output to the second output buffer 16 from a low level to a high level. As a result, after the third standby time T_{DESAT(FAULT)} has elapsed from a point in time when the output signal of the comparator 11 changed from a low level to a high level, the abnormality notification terminal voltage V_{FAULT} which corresponds to the abnormality notification signal output from the second output buffer 16 changes from a high level (V_{CC1}) to a low level (V_{GND}).

The control circuit 14c continues the overcurrent protection operation from a point in time when the abnormality notification terminal voltage V_{FAULT} changed to a low level (V_{GND}) until a fourth standby time T_{DESAT(MUTE)} has elapsed. In other words, the control circuit 14c continues to hold the level of the first control signal output to the first output buffer 13 at a high level until the fourth standby time T_{DESAT(MUTE)} has elapsed from a point in time when the abnormality notification terminal voltage V_{FAULT} changed to the low level (V_{GND}). The first output buffer 13 continues to output the gate drive signal having the negative power supply potential V_{EE} as long as the level of the first control signal is held at a high level. After the fourth standby time T_{DESAT(MUTE)} has elapsed from a point in time when the abnormality notification terminal voltage V_{FAULT} changed to the low level (V_{GND}), the control circuit 14c ends the overcurrent protection operation by changing the level of the first control signal from a high level to a low level.

After the fourth standby time T_{DESAT(MUTE)} has elapsed from a point in time when the abnormality notification terminal voltage V_{FAULT} changed to the low level (V_{GND}), the input terminal voltage V_{IN} changes to the high level (V_{CC1}) at a time t16. After a fifth standby time T_{RESET(FAULT)} has elapsed from the time t16, the control circuit 14c changes the second control signal to be output to the second output buffer 16 from a high level to a low level. As a result, after the fifth standby time T_{RESET(FAULT)} has elapsed from the time t16 when the input terminal voltage V_{IN} changed to the high level (V_{CC1}), the abnormality notification terminal voltage V_{FAULT} which corresponds to the abnormality notification signal output from the second output buffer 16 changes from the low level (V_{GND}) to the high level (V_{CC1}).

As described above, the overcurrent detection circuit 14 controls the second output buffer 16 so that the abnormality notification signal output from the second output buffer 16 changes from a high level to a low level after the third standby time T_{DESAT(FAULT)} has elapsed from a point in time when the output signal of the comparator 11 changes from a low level to a high level. The third standby time T_{DESAT(FAULT)} is an example of a first time. The overcurrent detection circuit 14 controls the second output buffer 16 by outputting a second control signal to the second output buffer 16.

The overcurrent detection circuit 14 changes the second control signal from a low level to a high level after the third standby time T_{DESAT(FAULT)} has elapsed from a point in time when the output signal of the comparator 11 changed from a low level to a high level. As described above, when the level of the second control signal is high, the second output buffer 16 outputs a low-level abnormality notification signal.

Specifically, the control circuit 14c of the overcurrent detection circuit 14 outputs the first control signal and the second control signal. The control circuit 14c sets the levels of the first control signal and the second control signal to a high level or a low level on the basis of the output signal of the comparator 11.

In the second embodiment, each of the threshold voltage adjustment circuit 10, the comparator 11, the overcurrent detection circuit 14, the ULVO circuit 15, and the second output buffer 16 is electrically connected to the ground terminal P4. These circuits operate with the ground potential V_{GND} as a reference. In the second embodiment, the input buffer 12 and the first output buffer 13 are each electrically connected to the negative power supply terminal P7. These circuits operate with the negative power supply potential V_{EE} as a reference.

As described above, when an overcurrent in the power element SW is detected, the power element SW is forcibly switched to the OFF state, and the abnormality notification terminal voltage V_{FAULT} corresponding to the abnormality notification signal changes from a high level to a low level. As a result, it is possible to prevent the occurrence of breakdowns and the like caused by the overcurrent, and to notify an external device of the occurrence of an abnormality.

On the other hand, it is assumed that an abnormality occurs in the power supply voltage, that is, the power supply voltage is lower than a predetermined value. In this case, the ULVO circuit 15 outputs a high-level voltage determination signal to the first output buffer 13 and the second output buffer 16. When the voltage determination signal is at a high level, the first output buffer 13 outputs a gate drive signal having the negative power supply potential V_{EE}. When the voltage determination signal is at a high level, the second output buffer 16 outputs a low-level abnormality notification signal. Thus, even when an abnormality occurs in the power supply voltage, the power element SW is forcibly switched to the OFF state, and the abnormality notification terminal voltage V_{FAULT} which corresponds to the abnormality notification signal changes from a high level to a low level. As a result, it is possible to prevent the occurrence of breakdowns and the like caused by an abnormality in the power supply voltage, and to notify an external device of the occurrence of an abnormality.

The semiconductor integrated circuit 1A of the second embodiment further includes the negative power supply terminal P7 to which the negative power supply potential V_{EE} which is a negative potential with respect to the ground potential is applied, in addition to the components included in the semiconductor integrated circuit 1 of the first embodiment. In the semiconductor integrated circuit 1A, the first output buffer 13 outputs a gate drive signal that changes between the negative power supply potential V_{EE} and the power supply potential V_{CC2} in synchronization with the timing signal. The overcurrent detection circuit 14 controls the first output buffer 13 so that the gate drive signal having the negative power supply potential V_{EE} is output after the output signal of the comparator 11 changes from a low level to a high level. According to such a semiconductor integrated circuit 1A, since the gate drive signal that changes between the negative power supply potential V_{EE} and the power supply potential V_{CC2} is supplied to the gate of the power element SW, self turn-on of the power element SW can be prevented.

Further, the semiconductor integrated circuit 1A also includes an abnormality notification terminal P8 that outputs an abnormality notification signal for notifying the occurrence of an abnormality, and a second output buffer 16 that generates an abnormality notification signal on the basis of the control signal (the second control signal) from the overcurrent detection circuit 14 and outputs the abnormality notification signal via the abnormality notification terminal P8. The overcurrent detection circuit 14 controls the second output buffer 16 so that the abnormality notification signal output from the second output buffer 16 changes from a high level to a low level after the third standby time T_{DESAT(FAULT)} has elapsed from a point in time when the output signal of the comparator 11 changed from a low level to a high level. According to such a semiconductor integrated circuit 1A, when an overcurrent in the power element SW is detected, the power element SW is forcibly switched to the OFF state, and the abnormality notification terminal voltage V_{FAULT} corresponding to the abnormality notification signal changes from a high level to a low level. As a result, it is possible to prevent the occurrence of breakdowns and the like caused by the overcurrent, and to notify an external device of the occurrence of an abnormality.

In order to avoid erroneous detection of an overcurrent due to noise from the power element SW, it is desirable to detect the threshold voltage V_{TH} in a region in which the noise from the power element SW is small, rather than constantly detecting the threshold voltage V_{TH} during a period while the semiconductor integrated circuit 1A is in operation. As shown in FIG. 10, as a first example, the threshold voltage V_{TH} is detected during a period TDI from a point in time when the output terminal voltage V_{OUT} fell to a low level and a sixth standby time TEN has elapsed to a point in time when the output terminal voltage V_{OUT} started to rise to a high level. As a second example, the threshold voltage V_{TH} is detected during a period T_{D2} from a point in time when the abnormality notification terminal voltage V_{FAULT} changed from a high level to a low level and the fourth standby time T_{DESAT(MUTE)} has elapsed to a point in time when the output terminal voltage V_{OUT} started to rise to a high level. These periods TDI and T_{D2} are periods during which the power element SW is reliably in the OFF state. In either case, since the threshold voltage V_{TH} is detected during the period in which the power element SW is in the OFF state, it becomes difficult to be affected by the noise from the power component SW. Furthermore, since the threshold voltage V_{TH} is adjusted intermittently, it is possible to follow a temperature change of a unit.

As described above, in order to detect the threshold voltage V_{TH} during a period when the power element SW is in the OFF state, the semiconductor integrated circuit 1A may include a threshold voltage detection circuit 40 disposed between the threshold voltage adjustment circuit 10 and the comparator 11. The threshold voltage detection circuit 40 passes the threshold voltage V_{TH} output from the threshold voltage adjustment circuit 10 through the comparator 11 and charges the capacitor 64 with the threshold voltage V_{TH} in a first period, and does not allow the threshold voltage V_{TH} output from the threshold voltage adjustment circuit 10 to pass through the comparator 11 and outputs a voltage between terminals of the capacitor 64 to the comparator 11 in a second period other than the first period. The first period is a period TDI from a point in time when the gate drive signal fell and the sixth standby time TEN has elapsed to a point in time when the gate drive signal started to rise, or a period T_{D2} from a point in time when the abnormality notification signal changed from a high level to a low level and the fourth standby time T_{DESAT(MUTE)} has elapsed to a point in time when the gate drive signal started to rise. The sixth standby time TEN is an example of a second time, and the fourth standby time T_{DESAT(MUTE)} is an example of a third time.

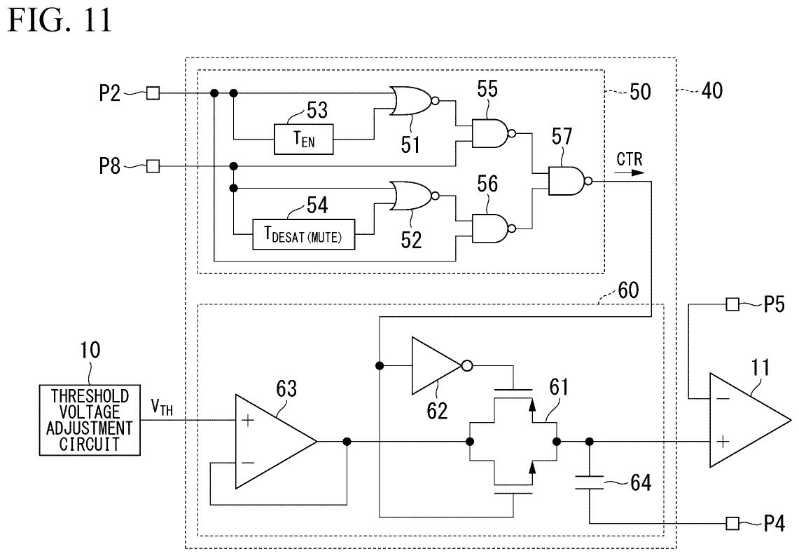

FIG. 11 is a circuit diagram showing an example of a configuration of the threshold voltage detection circuit 40. As shown in FIG. 11, the threshold voltage detection circuit 40 includes a timing generation circuit 50 and a sample-and-hold circuit 60.

The timing generation circuit 50 is electrically connected to the output terminal P2 and the abnormality notification terminal P8. The timing generation circuit 50 receives the output terminal voltage V_{OUT} and the abnormality notification terminal voltage V_{FAULT} as an input. In other words, the timing generation circuit 50 receives the gate drive signal and the abnormality notification signal as an input. The timing generation circuit 50 generates a sample timing signal CTR for controlling a sample timing of the threshold voltage V_{TH} on the basis of the gate drive signal and the abnormality notification signal, and outputs the sample timing signal CTR to the sample-and-hold circuit 60.

The timing generation circuit 50 outputs a high-level sample timing signal CTR in a first period, and outputs a low-level sample timing signal CTR in a second period other than the first period. The timing generation circuit 50 includes a first NOR circuit 51, a second NOR circuit 52, a first delay circuit 53, a second delay circuit 54, a first NAND circuit 55, a second NAND circuit 56, and a third NAND circuit 57.

One input terminal of two input terminals of the first NOR circuit 51 is electrically connected to the output terminal P2, and the other input terminal is electrically connected to the output terminal P2 via the first delay circuit 53. The first delay circuit 53 is a circuit that delays the gate drive signal by the sixth standby time TEN. One input terminal of two input terminals of the second NOR circuit 52 is electrically connected to the abnormality notification terminal P8, and the other input terminal is electrically connected to the abnormality notification terminal P8 via the second delay circuit 54. The second delay circuit 54 is a circuit that delays the abnormality notification signal by the fourth standby time T_{DESAT(MUTE)}.

One input terminal of two input terminals of the first NAND circuit 55 is electrically connected to an output terminal of the first NOR circuit 51, and the other input terminal is electrically connected to the abnormality notification terminal P8. One input terminal of two input terminals of the second NAND circuit 56 is electrically connected to an output terminal of the second NOR circuit 52, and the other input terminal is electrically connected to the output terminal P2. One input terminal of two input terminals of the third NAND circuit 57 is electrically connected to an output terminal of the first NAND circuit 55, and the other input terminal is electrically connected to an output terminal of the second NAND circuit 56. An output terminal of the third NAND circuit 57 is electrically connected to the sample-and-hold circuit 60. A signal output from the third NAND circuit 57 is the sample timing signal CTR.

The sample-and-hold circuit 60 performs sampling and holding of the threshold voltage V_{TH} on the basis of the sample timing signal CTR. The sample-and-hold circuit 60 includes an analog switch 61, an INV circuit 62, a voltage follower 63, and a capacitor 64.

An output terminal of the timing generation circuit 50, that is, an output terminal of the third NAND circuit 57 is electrically connected to a gate of an N-channel MOSFET of the analog switch 61. In addition, the output terminal of the timing generation circuit 50 is electrically connected to a gate of a P-channel MOSFET of the analog switch 61 via the INV circuit 62. The INV circuit 62 inverts the level of the sample timing signal CTR. When the sample timing signal CTR is at a high level, the analog switch 61 is in an ON state. When the sample timing signal CTR is at a low level, the analog switch 61 is in an OFF state.

An input terminal of the analog switch 61 is electrically connected to the output terminal (the threshold voltage output terminal 35) of the threshold voltage adjustment circuit 10 via the voltage follower 63. An output terminal of the analog switch 61 is electrically connected to the non-inverting input terminal of the comparator 11. One end of the capacitor 64 is electrically connected to the output terminal of the analog switch 61. The other end of the capacitor 64 is electrically connected to the ground terminal P4.

When the timing generation circuit 50 outputs a high-level sample timing signal CTR in the first period, the analog switch 61 is in the ON state, and the sample-and-hold circuit 60 is in a sample mode. Specifically, in the first period, the sample-and-hold circuit 60 passes the threshold voltage V_{TH} output from the threshold voltage adjustment circuit 10 through the comparator 11 and charges the capacitor 64 with the threshold voltage V_{TH}.

When the timing generation circuit 50 outputs a low-level sample timing signal CTR in the second period, the analog switch 61 is in the OFF state, and the sample-and-hold circuit 60 is in the hold mode. Specifically, in the second period, the sample-and-hold circuit 60 does not allow the threshold voltage V_{TH} output from the threshold voltage adjustment circuit 10 to pass through the comparator 11, and outputs the voltage between the terminals of the capacitor 64 to the comparator 11.

With the above-described configuration of the threshold voltage detection circuit 40, the threshold voltage V_{TH} output from the threshold voltage adjustment circuit 10 is directly input to the comparator 11 only during a first period in which the power element SW is in the OFF state, and the voltage between the terminals of the capacitor 64 charged in the first period is output to the comparator 11 as the threshold voltage V_{TH} during a second period other than the first period. As a result, erroneous detection of an overcurrent caused by noise from the power element SW can be more reliably avoided.

As shown in FIG. 10, it is necessary to perform sufficient sampling in the first period (T_{D1}, T_{D2}) which is relatively short, but an output impedance of the threshold voltage adjustment circuit 10 is relatively high. For this reason, it is desirable to sample an output of the threshold voltage adjustment circuit 10 after impedance conversion using the voltage follower 63. Moreover, instead of the sample-and-hold circuit 60, an A/D conversion circuit that receives the sample timing signal CTR output from the timing generation circuit 50 as a clock signal as an input may be used.

In each of the semiconductor integrated circuit 1 of the first embodiment and the semiconductor integrated circuit 1A of the second embodiment, the overcurrent detection circuit 14 may include a constant current source 14a that outputs, as a detection current I_{CHG}, a current proportional to the threshold voltage V_{TH} output from the threshold voltage adjustment circuit 10. When considering a short circuit tolerance of the power element SW, it is desirable to quickly raise the detection terminal voltage V_{DESAT} to the threshold voltage V_{TH} within a certain period of time, and thus it is desirable to output a larger detection current I_{CHG} from the overcurrent detection terminal P5 as the threshold voltage V_{TH} rises. The above demand can be met by the constant current source 14a that outputs the detection current I_{CHG} proportional to the threshold voltage V_{TH}.

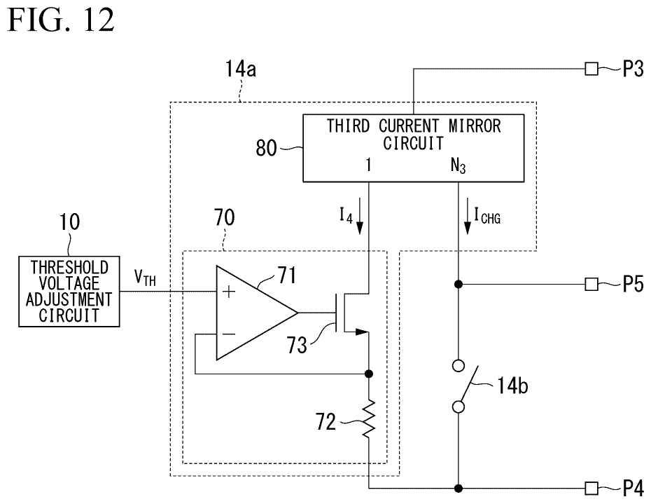

FIG. 12 is a circuit diagram showing an example of the configuration of a constant current source 14a that outputs the detection current I_{CHG} that is proportional to the threshold voltage V_{TH}. As shown in FIG. 12, the constant current source 14a includes a third voltage controlled current source 70 and a third current mirror circuit 80.

The third voltage controlled current source 70 outputs a fourth current I₄ that is proportional to the threshold voltage V_{TH}. The third voltage controlled current source 70 includes an operational amplifier 71, a resistor 72, and a MOSFET element 73. For example, the MOSFET element 73 is an N-channel MOSFET. A non-inverting input terminal of the operational amplifier 71 is electrically connected to an output terminal (the threshold voltage output terminal 35) of the threshold voltage adjustment circuit 10. The threshold voltage V_{TH} output from the threshold voltage adjustment circuit 10 is input to the non-inverting input terminal of the operational amplifier 71. An inverting input terminal of the operational amplifier 71 is electrically connected to a source of the MOSFET element 73. An output terminal of the operational amplifier 71 is electrically connected to a gate of the MOSFET element 73.

One end of the resistor 72 is electrically connected to the source of the MOSFET element 73. The other end of the resistor 72 is electrically connected to the ground terminal P4. A drain of the MOSFET element 73 is electrically connected to an input terminal of the third current mirror circuit 80. A current flowing from the drain of the MOSFET element 73 toward the resistor 72 is the fourth current I₄.

The third current mirror circuit 80 is electrically connected to the power supply terminal P3. An input terminal of the third current mirror circuit 80 is electrically connected to the drain of the MOSFET element 73. The third current mirror circuit 80 receives the fourth current I₄ as an input and outputs a current that is a multiple of the fourth current I₄ as the detection current I_{CHG}. For example, the third current mirror circuit 80 outputs the detection current I_{CHG} that is N₃ times the fourth current I₄. N₃ is a current mirror ratio. An output terminal of the third current mirror circuit 80 is electrically connected to the ground terminal P4 via the switch 14b. An output terminal of the third current mirror circuit 80 is also electrically connected to the overcurrent detection terminal P5.

The current I_{CHG} output from the constant current source 14a configured as above is expressed by the following Equation (28). In the following Equation (28), R₉ is a resistance value of the resistor 72, and ΔN₃ is a variation ratio of the current mirror ratio N₃ of the third current mirror circuit 80. As can be understood from the following Equation (28), the current I_{CHG} output from the constant current source 14a is directly affected by the variation ratio ΔR of the resistance values of the resistors but is proportional to the threshold voltage V_{TH}.

$$[ Equation 28 ]$$

$${I}_{CHG} \frac{{V}_{TH} {N}_{3}}{{R}_{9}} \cdot [ 1 + ε - Δ R + Δ {N}_{3} ] \qquad ( 28 )$$

With the constant current source 14a configured as described above, since the detection current I_{CHG} proportional to the threshold voltage V_{TH} output from the threshold voltage adjustment circuit 10 is output from the overcurrent detection terminal P5, the larger the detection current I_{CHG} can be output from the overcurrent detection terminal P5 as the threshold voltage V_{TH} rises. As a result, when an overcurrent occurs in the power element SW, the detection terminal voltage V_{DESAT} can be quickly raised to the threshold voltage V_{TH} within a certain period of time according to a magnitude of the threshold voltage V_{TH}.

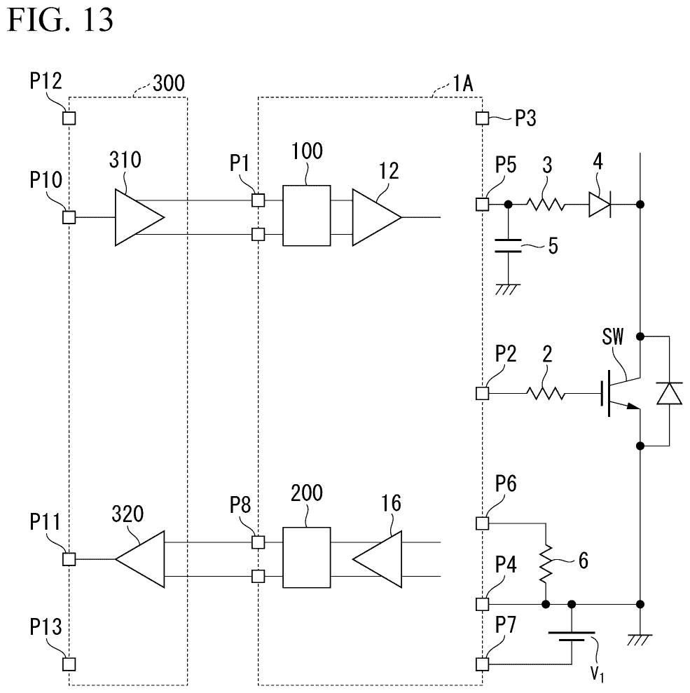

FIG. 13 is a circuit diagram showing an example of a semiconductor integrated circuit 1A including an insulation element. As shown in FIG. 13, the semiconductor integrated circuit 1A may further include a first insulation element 100 disposed between the input terminal P1 and the input buffer 12, and a second insulation element 200 disposed between the abnormality notification terminal P8 and the second output buffer 16. In the following description, the semiconductor integrated circuit 1A may be referred to as a secondary chip. In FIG. 13, the illustration of components other than the input buffer 12 and the second output buffer 16 are omitted.

A timing signal is output from a primary chip 300 to the secondary chip 1A, and an abnormality notification signal is output from the secondary chip 1A to the primary chip 300. The primary chip 300 includes a transmission circuit 310 that transmits a timing signal input to the primary chip 300 via a primary input terminal P10 to the secondary chip 1A. The input buffer 12 of the secondary chip 1A receives the timing signal transmitted from the transmission circuit 310 via the first insulation element 100. The primary chip 300 includes a reception circuit 320 that receives an abnormality notification signal transmitted from the second output buffer 16 of the secondary chip 1A via the second insulation element 200. The reception circuit 320 outputs an abnormality notification signal via a primary abnormality notification terminal P11.

For example, the primary chip 300 and the secondary chip 1A are connected by a bonding wire. The first insulation element 100 and the second insulation element 200 are insulated by a polyimide layer or an oxide film. Each of the first insulation element 100 and the second insulation element 200 may be either an isolation transformer using a transformer or an insulation capacitance using a capacitance. The primary chip 300 includes a primary power supply terminal P12 and a primary ground terminal P13 as terminals to which the power supply voltage used by the transmission circuit 310 and the reception circuit 320 are input. It is possible to transmit signals while the control side and the power element SW side are insulated from each other using the primary chip 300 as described above.

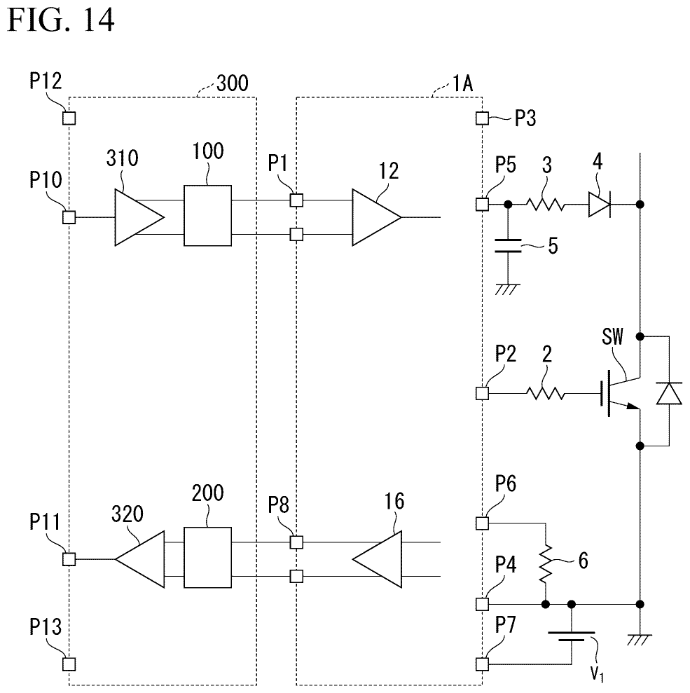

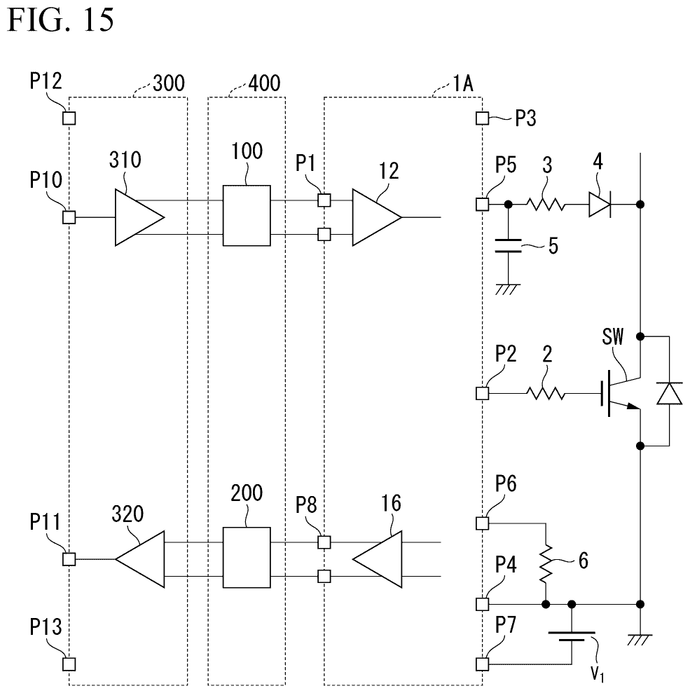

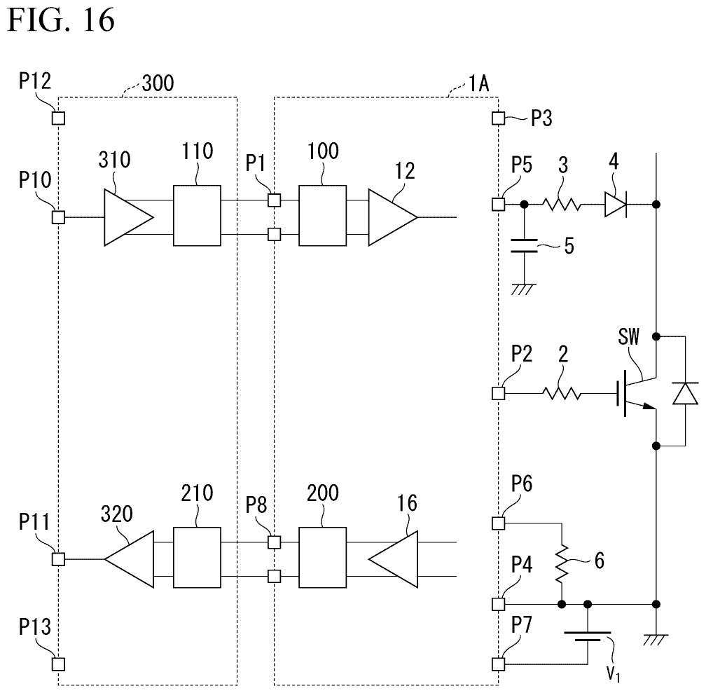

FIG. 14 is a circuit diagram showing an example in which the primary chip 300 includes an insulation element. As shown in FIG. 14, the primary chip 300 may include the first insulation element 100 and the second insulation element 200. FIG. 15 is a circuit diagram showing an example in which an insulation chip 400 including an insulation element is disposed between a primary chip 300 and a secondary chip 1A. As shown in FIG. 15, the insulation chip 400 disposed between the primary chip 300 and the secondary chip 1A may include the first insulation element 100 and the second insulation element 200. FIG. 16 is a circuit diagram showing an example in which both the primary chip 300 and the secondary chip 1A include insulation elements. As shown in FIG. 16, the secondary chip 1A may include a first insulation element 100 and a second insulation element 200, and the primary chip 300 may include a third insulation element 110 and a fourth insulation element 210.

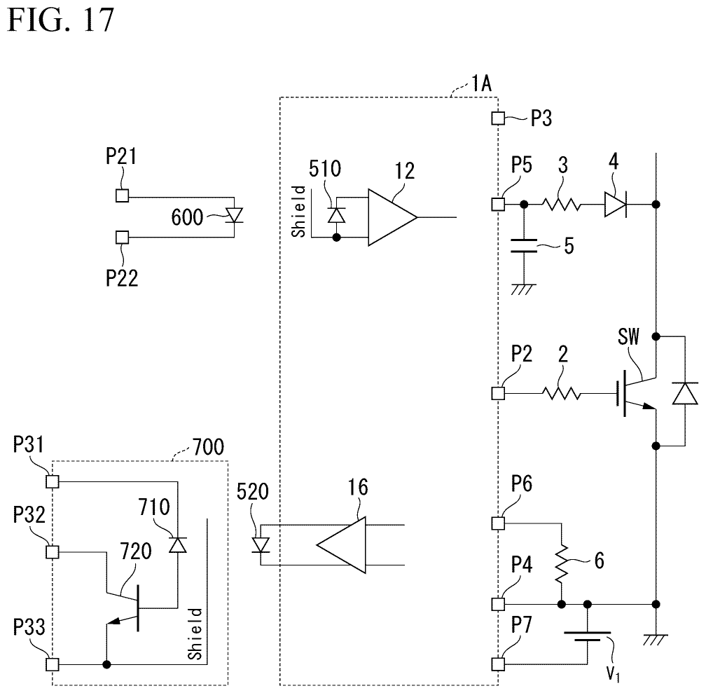

FIG. 17 is a circuit diagram showing a first example of the semiconductor integrated circuit 1A including an optical device as the insulation element. As shown in FIG. 17, the semiconductor integrated circuit 1A may include, as insulation elements, a first photodiode 510 connected to the input side of the input buffer 12 and a first light emitting diode 520 connected to the output side of the second output buffer 16.

The second light emitting diode 600 is connected between a terminal P21 and a terminal P22. When a current flows from the terminal P21 to the terminal P22, the second light emitting diode 600 emits light. The light emitted from the second light emitting diode 600 is received by the first photodiode 510 and is converted into a current. The input buffer 12 converts the current output from the first photodiode 510 into a voltage signal and outputs it. When an optical device is used as the insulation element, it is desirable for the input buffer 12 to include a trans-impedance amplifier (TIA) circuit.

The first light emitting diode 520 is driven by the second output buffer 16 to emit light. The light emitted from the first light emitting diode 520 is received by a second photodiode 710 included in a primary chip 700 and is converted into a current. In the primary chip 700, the second photodiode 710 is connected between a terminal P31 and a base of a transistor 720, and when a current flows through the second photodiode 710, the transistor 720 is in an ON state.

Although not shown, an external resistor is connected between the terminal P31 and the terminal P32. The terminal P33 is connected to the ground. When the first light emitting diode 520 emits light and the transistor 720 is in an ON state, a voltage of the terminal P32 is at a low level (a ground potential). In this manner, the primary chip 700 outputs the voltage of the terminal P32 as the abnormality notification signal. Since a small noise current flowing through the first photodiode 510 and the second photodiode 710 can cause malfunction, it is desirable to provide an electrostatic shield for the first photodiode 510 and the second photodiode 710. For example, in FIG. 17, the second light emitting diode 600, the primary chip 700, the first light emitting diode 520 and the semiconductor integrated circuit 1A are mounted in one semiconductor package. The second light emitting diode 600 and the primary chip 700 are mounted in one die pad, and the terminals P21, P22, P31, P32 and P33 are connected to outer leads of the semiconductor package. Furthermore, the first light emitting diode 520 and the semiconductor integrated circuit 1A are mounted in a die pad different from the above, and the terminals P2, P3, P4, P5, P6 and P7 are connected to outer leads of the semiconductor package.

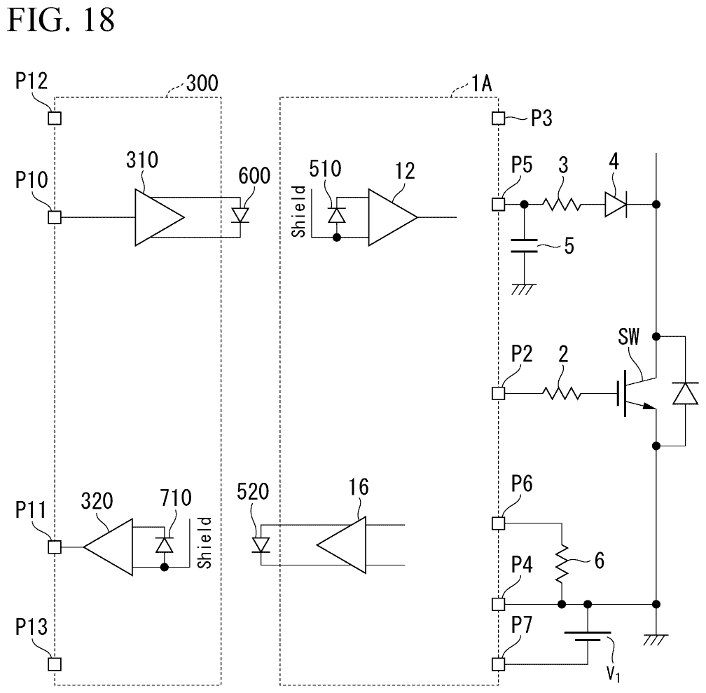

FIG. 18 is a circuit diagram showing a second example of the semiconductor integrated circuit 1A including an optical device as the insulation element. In the example shown in FIG. 17, an anode and a cathode of the second light emitting diode 600 are connected to the terminals P21 and P22, respectively, which are the input terminals on the primary side, and a collector of the transistor 720 is connected to the terminal P32 which is the output terminal on the primary side. Therefore, in the example shown in FIG. 17, the propagation delay time which is the time from when a signal is input to when it is output becomes long. In the example shown in FIG. 18, the second light emitting diode 600 is driven by the transmission circuit 310 of the primary chip 300, and a current output of the second photodiode 710 is received by the reception circuit 320, thereby outputting an abnormality notification signal from the primary abnormality notification terminal P11. According to the example shown in FIG. 18, the propagation delay time can be reduced compared to the example shown in FIG. 17. The primary abnormality notification terminal P11 is generally bundled with terminals that output other abnormality notification signals by wired logic connection. Therefore, it is desirable that the output terminal of the reception circuit 320 be of an open collector type or open drain type.

According to at least one embodiment described above, by having a reference current circuit that is formed on a substrate and outputs a reference current, and a trans-impedance circuit that has a plurality of resistors on the substrate and outputs a threshold voltage that is expressed as a function of the reference current and a combined resistance of the plurality of resistors and an external resistor, it is possible to provide a threshold voltage adjustment circuit that can easily adjust the threshold voltage by a simple method of simply changing a resistance value of the external resistor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A threshold voltage adjustment circuit comprising:
a reference current circuit formed on a substrate and configured to output a reference current; and
a trans-impedance circuit having a plurality of resistors on the substrate and configured to output a threshold voltage expressed as a function of the reference current and a combined resistance of the plurality of resistors and an external resistor.

2. The threshold voltage adjustment circuit according to claim 1, wherein the trans-impedance circuit includes:
a first current mirror circuit configured to receive the reference current as an input and to output a current that is a multiple of the reference current, a first resistor having one end electrically connected to an output terminal of the first current mirror circuit and the other end electrically connected to one end of the external resistor via a resistor connection terminal;
a second resistor having one end electrically connected to the other end of the first resistor and the other end electrically connected to the other end of the external resistor via a ground terminal; and
a threshold voltage output terminal electrically connected to one end of the first resistor and configured to output the threshold voltage.

3. The threshold voltage adjustment circuit according to claim 1, wherein the reference current circuit includes a reference voltage circuit configured to output the reference voltage, and a first voltage controlled current source configured to output a first current proportional to the reference voltage as the reference current.

4. The threshold voltage adjustment circuit according to claim 1, wherein the reference current circuit includes:
a reference voltage circuit configured to output the reference voltage, a first voltage controlled current source configured to output a first current proportional to the reference voltage;
a PTAT current source configured to output a second current proportional to absolute temperature; and
a second current mirror circuit configured to receive the second current as an input and to output a third current which is a current that is a multiple of the second current,
the reference current circuit outputs a current expressed by a difference between the first current and the third current as the reference current, and
the first current is greater than the third current.

5. The threshold voltage adjustment circuit according to claim 1, wherein the reference current circuit includes:
a reference voltage circuit configured to output the reference voltage, a first voltage controlled current source configured to output a first current proportional to the reference voltage; and
a PTAT current source configured to output a second current proportional to absolute temperature, and
the reference current circuit outputs a current expressed by a sum of the first current and the second current as the reference current.

6. The threshold voltage adjustment circuit according to claim 1, wherein the reference current circuit includes:
a reference voltage circuit configured to output the reference voltage; and
a first voltage controlled current source configured to output a first current proportional to the reference voltage as the reference current, and
the trans-impedance circuit includes:
a first resistor having one end electrically connected to one end of the external resistor via a power supply terminal and the other end electrically connected to the other end of the external resistor via a resistor connection terminal;
a second resistor having one end electrically connected to the other end of the first resistor and the other end electrically connected to an output terminal of the first voltage controlled current source;
a second voltage controlled current source configured to output a current proportional to a voltage of the resistor connection terminal;
a third resistor having one end electrically connected to an output terminal of the second voltage controlled current source and the other end electrically connected to a ground terminal; and
a threshold voltage output terminal electrically connected to one end of the third resistor and configured to output the threshold voltage.

7. A semiconductor integrated circuit which drives a gate of a power element, comprising:
an input terminal to which a timing signal is input;
an output terminal configured to output a gate drive signal that drives the gate;
an overcurrent detection terminal configured to output a detection current that detects an overcurrent of the power element;
a resistor connection terminal configured to connect an external resistor;
a ground terminal to which a ground potential is applied;
a power supply terminal to which a power supply potential that is a positive potential with respect to the ground potential is applied;
an input circuit to which the timing signal is input via the input terminal;
a first output circuit configured to generate the gate drive signal in synchronization with the timing signal input via the input circuit and to output the gate drive signal via the output terminal;
an overcurrent detection circuit configured to detect a rise of the timing signal input via the input circuit and then to output the detection current via the overcurrent detection terminal;
the threshold voltage adjustment circuit according to claim 1; and
a comparator configured to compare the threshold voltage output from the threshold voltage adjustment circuit with a detection terminal voltage that is a voltage of the overcurrent detection terminal and to output a signal indicating a comparison result to the overcurrent detection circuit,
wherein the comparator outputs a signal having a first level when the detection terminal voltage is equal to or lower than the threshold voltage, and outputs a signal having a second level when the detection terminal voltage exceeds the threshold voltage, and
the overcurrent detection circuit controls the first output circuit so that the gate drive signal having a potential at which the power element is in an OFF state is output after the output signal of the comparator changes from the first level to the second level.

8. The semiconductor integrated circuit according to claim 7, wherein the first output circuit outputs the gate drive signal that changes between the ground potential and the power supply potential in synchronization with the timing signal, and
the overcurrent detection circuit controls the first output circuit so that the gate drive signal having the ground potential is output after the output signal of the comparator changes from the first level to the second level.

9. The semiconductor integrated circuit according to claim 7, further comprising a negative power supply terminal to which a negative power supply potential that is a negative potential with respect to the ground potential is applied,
wherein the first output circuit outputs the gate drive signal that changes between the negative power supply potential and the power supply potential in synchronization with the timing signal, and
the overcurrent detection circuit controls the first output circuit so that the gate drive signal having the negative power supply potential is output after the output signal of the comparator changes from the first level to the second level.

10. The semiconductor integrated circuit according to claim 7, further comprising:
an abnormality notification terminal configured to output an abnormality notification signal that notifies occurrence of an abnormality; and
a second output circuit configured to generate the abnormality notification signal on the basis of a control signal from the overcurrent detection circuit and to output the abnormality notification signal via the abnormality notification terminal,
wherein the overcurrent detection circuit controls the second output circuit so that the abnormality notification signal output from the second output circuit changes from a third level to a fourth level after a first time has elapsed from a point in time when the output signal of the comparator changes from the first level to the second level.

11. The semiconductor integrated circuit according to claim 10, further comprising a threshold voltage detection circuit disposed between the threshold voltage adjustment circuit and the comparator,
wherein the threshold voltage detection circuit passes the threshold voltage output from the threshold voltage adjustment circuit through the comparator and charges a capacitor with the threshold voltage in a first period, and does not pass the threshold voltage output from the threshold voltage adjustment circuit through the comparator and outputs a voltage between terminals of the capacitor to the comparator in a second period other than the first period, and
the first period is a period from a point in time when a second time has elapsed since the gate drive signal fell to a point in time when the gate drive signal started to rise, or a period from a point in time when a third time has elapsed since the abnormality notification signal changed from the third level to the fourth level to a point in time when the gate drive signal started to rise.

12. The semiconductor integrated circuit according to claim 10, further comprising:
a first isolation circuit disposed between the input terminal and the input circuit; and
a second insulation circuit disposed between the abnormality notification terminal and the second output circuit.

13. The semiconductor integrated circuit according to claim 7, wherein the overcurrent detection circuit includes a constant current source that outputs, as the detection current, a current proportional to the threshold voltage output from the threshold voltage adjustment circuit.
